(19) United States
(12) Patent Application Publication
(10) Pub. No.: US 2025/0081760 A1
(43) Pub. Date: Mar. 6, 2025

(54) Display Substrate, Manufacturing Method Therefor, and Display Apparatus

(71) Applicants: Chengdu BOE Optoelectronics Technology Co., Ltd., Chengdu, Sichuan (CN); BOE Technology Group Co., Ltd., Beijing (CN)

(72) Inventors: Yuanjie XU, Beijing (CN); Weiyun HUANG, Beijing (CN); Yao HUANG, Beijing (CN)

(21) Appl. No.: 18/033,808

(22) PCT Filed: Mar. 24, 2022
(86) PCT No.: PCT/CN2022/082809

§ 371 Date: Apr. 26, 2023

(51) Int. Cl. H10K 59/131; H01L 27/12; H10K 59/12; H10K 59/121

(52) U.S. Cl. CPC H10K 59/131; H10K 59/1201; H10K 59/1213; H10K 59/1216; H10D 86/441; H10D 86/60

(57) ABSTRACT

A display substrate, a manufacturing Method therefor, and a display apparatus are disclosed. The display substrate includes a first display area (100) and a second display area (200), the first display area (100) includes a plurality of first light emitting devices (LD1), a plurality of first circuit units (QD1) and at least one second circuit unit (QD2), and the second display area (200) includes a plurality of second light emitting devices (LD2); the first circuit unit (QD1) includes at least a first anode electrode (51) connected to the first light emitting device (LD1) and a compensation capacitor plate (60) connected to the first anode electrode (51), the compensation capacitor plate (60) is configured to form a compensation capacitor; the second circuit unit (QD2) includes at least a second anode electrode (52), which is connected to the second light emitting device (LD2) through an anode connection line (70).

### CROSS-REFERENCE TO RELATED APPLICATION

The present application is a U.S. National Phase Entry of International Application No. PCT/CN2022/082809 having an international filing date of Mar. 24, 2022. The above-identified application is hereby incorporated by reference.

### TECHNICAL FIELD

The present disclosure relates to, but is not limited to, the field of display technologies, and particularly to a display substrate, a manufacturing method therefor, and a display apparatus.

### BACKGROUND

An Organic Light Emitting Diode (OLED for short) and a Quantum dot Light Emitting Diode (QLED for short) are active light emitting display devices and have advantages such as self-luminescence, a wide viewing angle, a high contrast ratio, low power consumption, extremely high response speed, lightness and thinness, flexibility, and low cost. With continuous development of display technologies, a display apparatus using the OLED or the QLED as a light emitting device and using a Thin Film Transistor (TFT) for signal control has become a mainstream product in the field of display at present.

### SUMMARY

The following is a summary of subject matters described herein in detail. The summary is not intended to limit the protection scope of claims.

In one aspect, the present disclosure provides a display substrate, including a first display area and a second display area, the first display area at least partially surrounds the second display area, the first display area is configured to perform image display and includes a plurality of first light emitting devices, a plurality of first circuit units and at least one second circuit unit, the second display area is configured to perform image display and transmitting light and includes a plurality of second light emitting devices; the first circuit unit includes a first pixel drive circuit, the first pixel drive circuit includes at least a first anode electrode connected with the first light emitting device and a compensation capacitor plate connected with the first anode electrode, the compensation capacitor plate is configured to form a compensation capacitor; the second circuit unit includes a second pixel drive circuit, the second pixel drive circuit at least includes a second anode electrode, and the second anode electrode is connected with the second light emitting device through an anode connection line.

In an exemplary implementation, the first anode electrode, the second anode electrode and the compensation capacitor plate are disposed in a same layer and are synchronously formed through the same patterning process.

In an exemplary implementation, the first anode electrode and the compensation capacitor plate are interconnected to be of an integral structure.

In an exemplary implementation, at least one second circuit unit includes a power connection line extending along a first direction and a first power supply line extending along a second direction, the first power supply line is connected with the power connection line through a via, the first circuit unit includes a power connection line extending along the first direction, the first direction and the second direction intersect.

In an exemplary implementation, the first circuit unit includes a power connection line extending along the first direction, and at least one first circuit unit is not provided with the first power supply line.

In an exemplary implementation, the compensation capacitor plate and the first power supply line are disposed in a same layer and are synchronously formed through the same patterning process.

In an exemplary implementation, the first circuit unit and the second circuit unit each include a storage capacitor, the storage capacitor includes a first plate and a second plate, the orthographic projection of the second plate on a base substrate at least partially overlaps the orthographic projection of the first plate on the base substrate; the second plate of the first circuit unit is connected with the second plate of the first circuit unit adjacent in the first direction through a plate connection line to form the power connection line, alternatively, the second plate of the first circuit unit is connected with the second plate of the second circuit unit adjacent in the first direction through a plate connection line to form the power connection line, alternatively, the second plate of the second circuit unit is connected with the second plate of the second circuit unit adjacent in the first direction through a plate connection line to form the power connection line.

In an exemplary implementation, the orthographic projection of the compensation capacitor plate on the base substrate at least partially overlaps the orthographic projection of the second plate of the first circuit unit on the base substrate.

In an exemplary implementation, the first pixel drive circuit and the second pixel drive circuit further include a first transistor as a reset transistor, a second transistor as a compensation transistor, and a third transistor as a drive transistor, a gate electrode of the first transistor is connected with a second scan signal line, a first electrode of the first transistor is connected with a first initial signal line, a second electrode of the first transistor is connected with a first electrode of the second transistor and a gate electrode of the third transistor, respectively, a gate electrode of the second transistor is connected with a first scan signal line, and a second electrode of the second transistor is connected with a second electrode of the third transistor; the orthographic projection of the compensation capacitor plate on the base substrate at least partially overlaps the orthographic projection of the second electrode of the first transistor of the first pixel drive circuit on the base substrate.

In an exemplary implementation, the orthographic projection of the compensation capacitor plate on the base substrate at least partially overlaps the orthographic projection of the first electrode of the first transistor of the first pixel drive circuit on the base substrate.

In an exemplary implementation, the first pixel drive circuit and the second pixel drive circuit further include a fourth transistor as a data writing transistor and a fifth transistor as a light emitting control transistor, a gate electrode of the fourth transistor is connected with the first scan signal line, a first electrode of the fourth transistor is connected with a data signal line, a second electrode of the fourth transistor is connected with a first electrode of the third transistor, a gate electrode of the fifth transistor is connected with a light emitting control line, a first electrode of the fifth transistor is connected with a second plate of the storage capacitor, and the second electrode of the fifth transistor is connected with the first electrode of the third transistor; the orthographic projection of the compensation capacitor plate on the base substrate at least partially overlaps the orthographic projection of the first electrode of the fifth transistor of the first pixel drive circuit on the base substrate.

In an exemplary implementation, the first pixel drive circuit and the second pixel drive circuit further include a sixth transistor as a light emitting control transistor, a gate electrode of the sixth transistor is connected with the light emitting control line, a first electrode of the sixth transistor is connected with the second electrode of the third transistor, the first anode electrode is connected with a second electrode of the sixth transistor of the first circuit unit through a via, and the second anode electrode is connected with the second electrode of the sixth transistor of the second circuit unit through a via.

In an exemplary implementation, the first pixel drive circuit and the second pixel drive circuit further include a seventh transistor as a reset transistor, a gate electrode of the seventh transistor is connected with the second scan signal line, a first electrode of the seventh transistor is connected with a second initial signal line, and a second electrode of the seventh transistor is connected with the second electrode of the sixth transistor.

In an exemplary implementation, the first pixel drive circuit and the second pixel drive circuit further include a shield electrode connected to the first initial signal line, and the orthographic projection of the compensation capacitor plate on the base substrate at least partially overlaps the orthographic projection of the shield electrode of the first pixel drive circuit on the base substrate.

In an exemplary implementation, a first end of the anode connection line is connected with the second anode electrode through a via, and a second end of the anode connection line extends to the second display area and is connected with a second anode of the second light emitting device.

In an exemplary implementation, in a plane perpendicular to the display substrate, the first display area includes a first substrate structure layer disposed on a base substrate and a first light emitting structure layer disposed on a side of the first substrate structure layer away from the base substrate, the first substrate structure layer includes a plurality of first circuit units and at least one second circuit unit, and the first light emitting structure layer includes a plurality of first light emitting devices; the second display area includes a second substrate structure layer disposed on the base substrate and a second light emitting structure layer disposed on a side of the second substrate structure layer away from the base substrate, the second substrate structure layer includes a plurality of insulation layers, and the second light emitting structure layer includes a plurality of second light emitting devices.

In an exemplary implementation, the first substrate structure layer includes a first conductive layer, a second conductive layer, a third conductive layer and a fourth conductive layer provided sequentially on the base substrate, the first conductive layer includes gate electrodes of a plurality of transistors in the first pixel drive circuit and the second pixel drive circuit and a first plate of a storage capacitor, the second conductive layer includes a second plate of the storage capacitor, the third conductive layer includes first electrodes and second electrodes of the plurality of transistors, and the fourth conductive layer includes the first anode electrode, the second anode electrode and the compensation capacitor plate.

In an exemplary implementation, the fourth conductive layer further includes a first power supply line disposed at the second circuit unit.

In another aspect, the present disclosure further provides a display apparatus, including the aforementioned display substrate.

On the other hand, the invention further provides a manufacturing method for a display substrate, the display substrate includes a first display area and a second display area, the first display area at least partially surrounds the second display area, the first display area is configured to perform image display and includes a plurality of first light emitting devices, a plurality of first circuit units and at least one second circuit unit, the second display area is configured to perform image display and transmitting light and includes a plurality of second light emitting devices; the manufacturing method includes:

Forming a first circuit unit and a second circuit unit; the first circuit unit includes a first pixel drive circuit including at least a first anode electrode and a compensation capacitor plate connected with the first anode electrode, the compensation capacitor plate is configured to form a compensation capacitor; the second circuit unit includes a second pixel drive circuit which includes at least a second anode electrode;

Forming a first light emitting device and a second light emitting device; the first light emitting device is connected with the first anode electrode, and the second light emitting device is connected with the second anode electrode through an anode connection line.

Other aspects may be understood upon reading and understanding the drawings and detailed description.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1 is a schematic diagram of a structure of a display apparatus.

FIG. 2 is a schematic diagram of a structure of a display substrate.

FIG. 3 is a schematic diagram of a planar structure of a first light emitting structure layer in a display substrate;

FIG. 4 is a schematic diagram of a planar structure of a second light emitting structure layer in a display substrate;

FIG. 5 is a schematic diagram of a planar structure of a first substrate structure layer in a display substrate;

FIG. 6 is a schematic diagram of a sectional structure of a first display area in a display substrate.

FIG. 7 is a schematic diagram of a sectional structure of a second display area in a display substrate.

FIG. 8 is a schematic diagram showing a connection between a pixel drive circuit and a light emitting device;

FIG. 9a is an equivalent circuit diagram of a first pixel drive circuit;

FIG. 9b is an equivalent circuit diagram of a second pixel drive circuit;

FIG. 10 is a schematic diagram of a planar structure of a display substrate according to an exemplary embodiment of the present disclosure.

FIG. 11 is a schematic diagram obtained after a pattern of a semiconductor layer is formed according to an embodiment of the present disclosure;

FIG. 12a and FIG. 12b are schematic diagrams obtained after a pattern of a first conductive layer is formed according to an embodiment of the present disclosure.

FIG. 13a and FIG. 13b are schematic diagrams obtained after a pattern of a second conductive layer is formed according to an embodiment of the present disclosure.

FIG. 14 is a schematic view obtained after a pattern of a fourth insulation layer is formed according to an embodiment of the present disclosure.

FIG. 15a and FIG. 15b are schematic diagrams obtained after a pattern of a third conductive layer is formed according to an embodiment of the present disclosure.

FIG. 16 is a schematic diagram obtained after a pattern of a first planarization layer is formed according to an embodiment of the present disclosure.

FIG. 17a and FIG. 17b are schematic diagrams obtained after a pattern of a fourth conductive layer is formed according to an embodiment of the present disclosure.

FIG. 18 is a schematic diagram after a pattern of a second planarization layer is formed according to an embodiment of the present disclosure.

FIG. 19 is a schematic diagram of an equivalent circuit of a first pixel drive circuit according to an embodiment of the present disclosure.

Description of reference signs:

| | | |
|---|---|---|
| 11-first active layer; | 12-second active layer; | 13-third active layer; |
| 14-fourth active layer; | 15-fifth active layer; | 16-sixth active layer; |
| 17-seventh active layer; | 21-first scan signal line | 22-second scan signal line |
| 23- light emitting control line; | 24-first plate; | 31-first initial signal line; |
| 32-second initial signal line; | 33-second plate; | 34-shield electrode; |
| 35-plate connection line; | 36-opening; | 37-power connection line; |
| 41-first connection electrode; | 42-second connection | 43-third connection electrode; |
| | electrode; | |
| 44-fourth connection | 45-fifth connection electrode; | 46-sixth connection electrode; |
| electrode; | | |
| 51-first anode electrode; | 52-second anode electrode; | 53-data signal line; |
| 54-first power supply line; | 60-compensation capacitor | 70-anode connection line; |
| | plate; | |
| 100-first display area; | 101-base substrate; | 102-first substrate structure |
| | | layer; |
| 103-first light emitting | 104-first encapsulation | 110-first pixel drive area; |
| structure layer; | structure layer; | |
| 120-second pixel drive area; | 200-second display area; | 202-second substrate structure |
| | | layer; |
| 203-second light emitting | 204-second encapsulation | 210-transistor; |
| structure layer; | structure layer; | |
| 211-storage capacitor; | 301-first anode; | 302-second anode; |

### DETAILED DESCRIPTION

To make objectives, technical solutions, and advantages of the present disclosure clearer, the embodiments of the present disclosure will be described in detail with reference to the accompanying drawings. It is to be noted that implementations may be implemented in a plurality of different forms. Those of ordinary skills in the art may easily understand such a fact that implementations and contents may be transformed into various forms without departing from the purpose and scope of the present disclosure. Therefore, the present disclosure should not be explained as being limited to contents described in following implementations only. The embodiments in the present disclosure and features in the embodiments may be combined randomly with each other if there is no conflict. In order to keep following description of the embodiments of the present disclosure clear and concise, detailed descriptions about part of known functions and known components are omitted in the present disclosure. The drawings of the embodiments of the present disclosure only involve structures involved in the embodiments of the present disclosure, and other structures may refer to usual designs.

Scales of the drawings in the present disclosure may be used as a reference in the actual process, but are not limited thereto. For example, the width-length ratio of the channel, the thickness and spacing of various film layer, and the width and spacing of various signal line may be adjusted according to actual needs. The number of pixels in the display substrate and the number of sub-pixels in each pixel are not limited to the numbers shown in the drawings. The drawings described in the present disclosure are schematic structure diagrams only, and one implementation of the present disclosure is not limited to the shapes, numerical values or the like shown in the drawings.

Ordinal numerals such as “first”, “second”, and “third” in the specification are set to avoid confusion of constituent elements, but not to set a limit in quantity.

In the specification, for convenience, wordings indicating orientation or positional relationships, such as “middle”, “upper”, “lower”, “front”, “back”, “vertical”, “horizontal”, “top”, “bottom”, “inside”, and “outside”, are used for illustrating positional relationships between constituent elements with reference to the drawings, and are merely for facilitating the description of the specification and simplifying the description, rather than indicating or implying that a referred apparatus or element must have a particular orientation and be constructed and operated in the particular orientation. Therefore, they cannot be understood as limitations on the present disclosure. The positional relationships between the constituent elements may be changed as appropriate according to directions for describing the various constituent elements. Therefore, appropriate replacements may be made according to situations without being limited to the wordings described in the specification.

In the specification, unless otherwise specified and defined explicitly, terms “mount”, “mutually connect”, and “connect” should be understood in a broad sense. For example, the connection may be a fixed connection, a detachable connection or an integrated connection. It may be a mechanical connection or an electrical connection. It may be a direct mutual connection, or an indirect connection through middleware, or internal communication between two components. Those of ordinary skill in the art may understand specific meanings of these terms in the present disclosure according to specific situations.

In the specification, a transistor refers to a component which includes at least three terminals, i.e., a gate electrode, a drain electrode and a source electrode. The transistor has a channel region between the drain electrode (drain electrode terminal, drain region, or drain) and the source electrode (source electrode terminal, source region, or source), and a current may flow through the drain electrode, the channel region, and the source electrode. It is to be noted that, in the specification, the channel region refers to a region through which the current mainly flows.

In the specification, a first electrode may be a drain electrode, and a second electrode may be a source electrode. Or, the first electrode may be the source electrode, and the second electrode may be the drain electrode. In cases that transistors with opposite polarities are used, a current direction changes during operation of a circuit, or the like, functions of the “source electrode” and the “drain electrode” are sometimes interchangeable. Therefore, the “source electrode” and the “drain electrode”, as well as the “source terminal” and the “drain terminal” are interchangeable in the specification.

In the specification, “electrical connection” includes a case that constituent elements are connected together through an element with a certain electrical effect. The “element with the certain electrical effect” is not particularly limited as long as electrical signals may be sent and received between the connected constituent elements. Examples of the “element with the certain electrical effect” not only include electrodes and wirings, but also include switch elements such as transistors, resistors, inductors, capacitors, other elements with various functions, etc.

In the specification, “parallel” refers to a state in which an angle formed by two straight lines is above −10° and below 10°, and thus also includes a state in which the angle is above −5° and below 5°. In addition, “perpendicular” refers to a state in which an angle formed by two straight lines is above 80° and below 100°, and thus also includes a state in which the angle is above 85° and below 95°.

In the specification, a “film” and a “layer” are interchangeable. For example, a “conductive layer” may be replaced with a “conductive film” sometimes. Similarly, an “insulating film” may be replaced with an “insulation layer” sometimes.

Triangle, rectangle, trapezoid, pentagon and hexagon in this specification are not strictly defined, and they may be approximate triangle, rectangle, trapezoid, pentagon or hexagon, etc. There may be some small deformation caused by tolerance, and there may be chamfer, arc edge and deformation, etc.

In the present disclosure, “about” refers to that a boundary is defined not so strictly and numerical values within process and measurement error ranges are allowed.

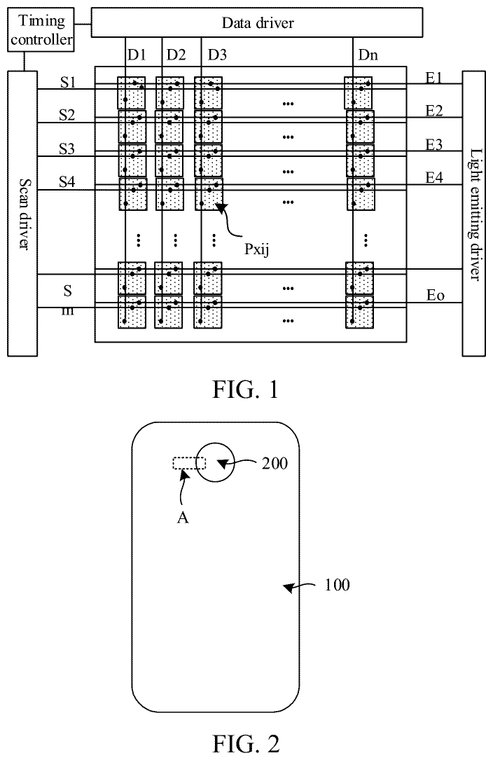

FIG. 1 is a schematic diagram of a structure of a display apparatus. As shown in FIG. 1, the display apparatus may include a timing controller, a data driver, a scan driver, a light emitting driver and a pixel array. The timing controller is connected to the data driver, the scan driver and the light emitting driver, respectively, the data driver is connected to a plurality of data signal lines (D1 to Dn) respectively, the scan driver is connected to a plurality of scan signal lines (S1 to Sm) respectively, and the light emitting driver is connected to a plurality of light emitting signal lines (E1 to Eo) respectively. The pixel array may include a plurality of sub-pixels Pxij, i and j may be natural numbers, at least one sub-pixel Pxij may include a circuit unit and a light emitting device connected to the circuit unit, and the circuit unit may include at least one scan signal line, at least one data signal line, at least one light emitting signal line and a pixel drive circuit. In an exemplary implementation, the timing controller may provide a gray tone value and a control signal, which are suitable for a specification of the data driver, to the data driver, provide a clock signal, a scan start signal, etc., which are suitable for a specification of the scan driver, to the scan driver, and provide a clock signal, a emitting stop signal, etc., which are suitable for a specification of the light emitting driver, to the light emitting driver. The data driver may generate a data voltage to be provided to the data signal lines D1, D2, D3, . . . , and Dn by using the gray tone value and the control signal that are received from the timing controller. For example, the data driver may sample the gray tone value by using the clock signal and apply a data voltage corresponding to the gray tone value to the data signal lines D1 to Dn by taking a pixel row as a unit, wherein n may be a natural number. The scan driver may receive the clock signal, the scan start signal, etc., from the timing controller to generate a scan signal to be provided to the scan signal lines S1, S2, S3, . . . , and Sm. For example, the scan driver may provide a scan signal with an on-level pulse to the scan signal lines S1 to Sm sequentially. For example, the scan driver may be constructed in a form of a shift register and may generate a scan signal in a manner in which the scan start signal provided in a form of an on-level pulse is transmitted to a next-stage circuit sequentially under the control of the clock signal, wherein m may be a natural number. The light emitting driver may receive a clock signal, a emitting stop signal, etc., from the timing controller to generate a emitting signal to be provided to the light emitting signal lines E1, E2, E3, . . . , and Eo. For example, the light emitting driver may provide a emitting signal with an off-level pulse to the light emitting signal lines E1 to Eo sequentially. For example, the light emitting driver may be constructed in a form of a shift register and may generate a emitting signal in a manner in which the emitting stop signal provided in a form of an off-level pulse is transmitted to a next-stage circuit sequentially under the control of the clock signal, wherein o may be a natural number.

With the development of display technology, products such as full screen or narrow bezel displays have gradually become a development trend of display products due to their large screen-to-body ratio and ultra-narrow bezel. For a product such as an intelligent terminal, a front camera, a fingerprint sensor, or a light sensor usually needs to be arranged. In order to increase screen-to-body ratio, Full display with camera technology (FDC for short) or under-screen fingerprint technology is usually adopted for a product with full screen or narrow bezel, and sensors such as cameras are placed in a Under Display Camera (UDC for short) area of the display substrate. The UDC area not only has certain transmittance, but also has display function, achieving Full Display in Camera (FDC for short).

FIG. 2 is a schematic diagram of a structure of a display substrate. As shown in FIG. 2, in a plane parallel to the display substrate, the display substrate may include a first display area 100 and a second display area 200, and the first display area 100 may at least partially surround the second display area 200. In an exemplary implementation, the first display area 100 is configured to perform image display and may be referred to as a normal display area. The position of the second display area 200 may correspond to the position of an optical apparatus, the second display area 200 is configured to perform image display and transmit light, the transmitted light is received by the optical apparatus, and the second display area 200 may be referred to as an under-screen camera display area.

In an exemplary implementation, the position of the second display area 200 in the first display area 100 may not be limited and may be located at an upper or lower part of the first display area 100 or may be located at an edge position of the first display area 100. In an exemplary implementation, in a plane parallel to the display substrate, the shape of the second display area 200 may be any one or more of following: a square, a rectangle, a polygon, a circle, an ellipse, and the like, and the optical apparatus may be an optical sensor such as a fingerprint recognition apparatus, a camera apparatus, or 3D imaging apparatus. When the shape of the second display area 200 is a circle, the diameter of the circle may be about 3 mm to 5 mm, and when the shape of the second display area 200 is a rectangle, the side length of the rectangle may be about 3 mm to 5 mm, which is not limited in the present disclosure.

In an exemplary implementation, the resolutions of the first display area 100 and the second display area 200 may be the same or the resolution of the second display area 200 may be less than the resolution of the first display area 100. For example, the resolution of the second display area 200 may be about 50% to 70% of the resolution of the first display area 100. Resolution (such as Pixels Per Inch, PPI for short) refers to the quantity of pixels per unit area, which can be called pixel density. The higher the PPI value, the higher the density of the display substrate to display the picture, and the richer the details of the picture.

In an exemplary implementation, in a plane perpendicular to the display substrate, the first display area 100 may include a first substrate structure layer disposed on the base substrate and a first light emitting structure layer disposed on a side of the first substrate structure layer away from the base substrate. The second display area 200 may include a second substrate structure layer disposed on the base substrate and a second light emitting structure layer disposed on a side of the second substrate structure layer away from the base substrate.

In an exemplary implementation, the first substrate structure layer of the first display area 100 may include a plurality of circuit units which may include at least a pixel drive circuit, and the first substrate structure layer may be referred to as a drive structure layer. The first light emitting structure layer of the first display area 100 may include a plurality of normal sub-pixels, a normal sub-pixel may include a first light emitting device, the first light emitting device may at least include a first anode, the first anode of at least one normal sub-pixel is connected to a pixel drive circuit of at least one circuit unit, the pixel drive circuit is configured to directly output a corresponding current to the connected first light emitting device, the first light emitting device is configured to emit light of a corresponding brightness in response to the current output by the connected pixel drive circuit.

In an exemplary implementation, the second substrate structure layer of the second display area 200 includes a plurality of insulation layers stacked and may be referred to as a composite insulation layer. The second light emitting structure layer of the second display area 200 may include a plurality of functional sub-pixels, a functional sub-pixel may include a second light emitting device, the second light emitting device may include at least a second anode, the second anode of at least one functional sub-pixel is connected to a pixel drive circuit of at least one circuit unit in the first display area 100 through an anode connection line, the pixel drive circuit is configured to output a corresponding current to the connected second light emitting device through the anode connection line, and the second light emitting device is configured to emit light of a corresponding brightness in response to the current output by the connected pixel drive circuit.

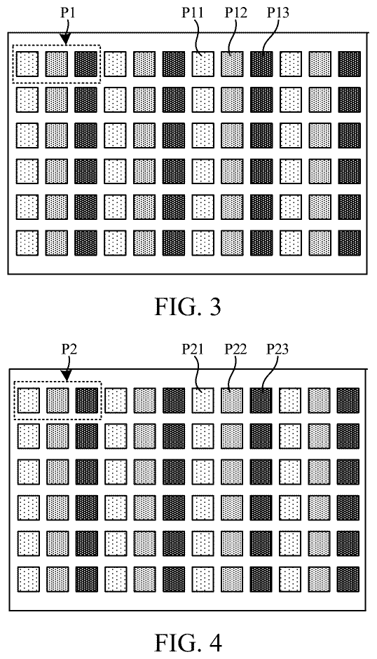

FIG. 3 is a schematic diagram of a planar structure of a first light emitting structure layer in a display substrate, illustrating the planar structure of the first light emitting structure layer of the first display area. In an exemplary implementation, the first light emitting structure layer of the first display area may include a plurality of normal pixel units P1 arranged in a matrix, at least one normal pixel unit P1 may include a first normal sub-pixel P11 emitting light of a first color, a second normal sub-pixel P12 emitting light of a second color, and a third normal sub-pixel P13 emitting light of a third color. All three normal sub-pixels each may include a first light emitting device. In an exemplary implementation, the first normal sub-pixel P11 may be a red sub-pixel (R) emitting red light, the second normal sub-pixel P12 may be a blue sub-pixel (B) emitting blue light, the third normal sub-pixel P13 may be a green sub-pixel (G) emitting green light, a shape of a sub-pixel may be a rectangle, a rhombus, a pentagon, or a hexagon, and the three normal sub-pixels may be arranged side by side horizontally, side by side vertically, or in a manner like a Chinese character “we”, etc., and the present disclosure is not limited herein.

FIG. 4 is a schematic diagram of a planar structure of a second light emitting structure layer in a display substrate, illustrating the planar structure of the second light emitting structure layer of the second display area. In an exemplary implementation, the second light emitting structure layer of the second display area may include a plurality of functional pixel units P2 arranged in a matrix, at least one functional pixel unit P2 may include a first functional sub-pixel P21 emitting light of a first color, a second functional sub-pixel P22 emitting light of a second color, and a third functional sub-pixel P23 emitting light of a third color, each of the three functional sub-pixels may include a second light emitting device. In an exemplary implementation, the first functional sub-pixel P21 may be a red sub-pixel (R) emitting red light, the second functional sub-pixel P22 may be a blue sub-pixel (B) emitting blue light, the third functional sub-pixel P23 may be a green sub-pixel (G) emitting green light, the shape of the sub-pixel may be a rectangle, a rhombus, a pentagon, or a hexagon, and the three functional sub-pixels may be arranged side by side horizontally, side by side vertically, or in a manner like a Chinese character “ [symbol] ”, etc., and the present disclosure is not limited herein.

In an exemplary implementation, the normal pixel unit P1 may include four normal sub-pixels, the functional pixel unit P2 may include four functional sub-pixels, and the normal sub-pixels or the functional sub-pixels may be arranged side by side horizontally, side by side vertically, in a diamond-shaped manner, etc., and the present disclosure is not limited herein.

In an exemplary implementation, the arrangement of the normal pixel units in the first display area and the arrangement of the functional pixel units in the second display area may be the same, or different, the number of normal sub-pixels included in the normal pixel unit and the number of functional sub-pixels included in the functional pixel unit may be the same or different, and the arrangement of the normal sub-pixels in the normal pixel unit may be the same or different from the arrangement of the functional sub-pixels in the functional pixel unit, and the present disclosure is not limited herein.

In an exemplary implementation, a plurality of normal sub-pixels or functional sub-pixels sequentially provided in a horizontal direction may be referred to as a pixel row, and a plurality of normal sub-pixels or functional sub-pixels sequentially arranged in a vertical direction may be referred to as a pixel column, and a plurality of pixel rows and a plurality of pixel columns form a pixel array arranged in an array.

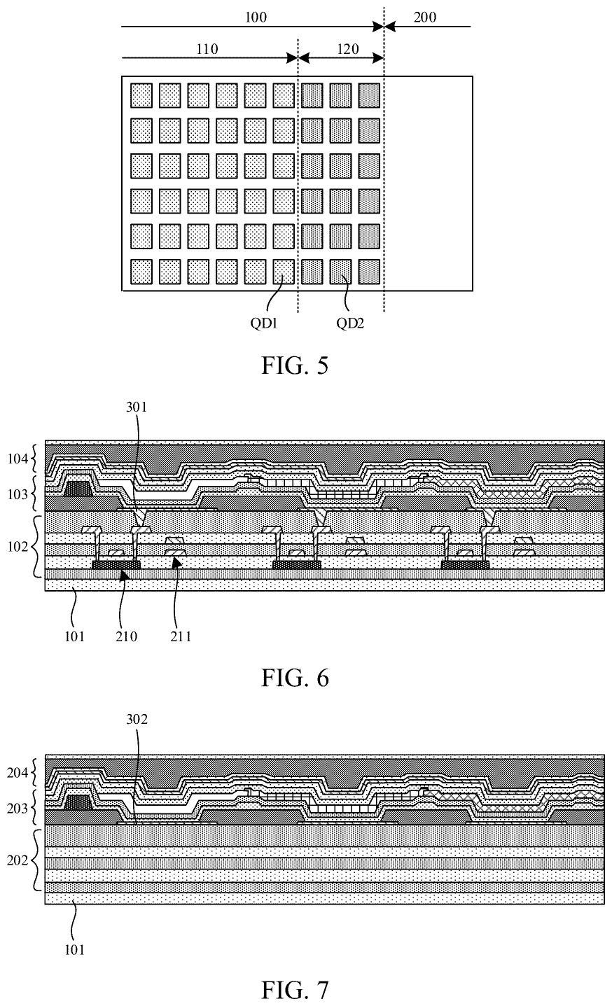

FIG. 5 is a schematic diagram of a planar structure of a first substrate structure layer in a display substrate, which is an enlarged view of a region A in FIG. 2, and illustrates a planar structure of the first substrate structure layer in a region close to the second display area 200 in the first display area 100. In an exemplary implementation, in a plane parallel to the display substrate, the first substrate structure layer of the first display area 100 may include a first pixel drive area 110 and a second pixel drive area 120, the second pixel drive area 120 may be located on a side of the first pixel drive area 110 close to the second display area 200, the first pixel drive area 110 may include a plurality of first circuit units QD1, and the second pixel drive area 120 may include a plurality of second circuit units QD2.

In an exemplary implementation, at least one first circuit unit QD1 may include a first pixel drive circuit connected with at least one first light emitting device of the first display area 100, the first pixel drive circuit is configured to directly output a corresponding current to the connected first light emitting device so that the first light emitting device emits light of a corresponding brightness.

In an exemplary implementation, at least one second circuit unit QD2 may include a second pixel drive circuit, the second pixel drive circuit is connected with at least one second light emitting device of the second display area 200 through an anode connection line. The second pixel drive circuit is configured to output a corresponding current to the connected second light emitting device through the anode connection line, so that the second light emitting device emits light of a corresponding brightness.

In an exemplary implementation, circuit units described in the present disclosure are regions divided according to a substrate structure layer, each circuit unit includes a pixel drive circuit, and sub-pixels described in the present disclosure are regions divided according to a light emitting structure layer, each sub-pixel includes a light emitting device. In an exemplary implementation, positions of both the sub-pixels and the circuit units may be corresponding or the positions of both the sub-pixels and the circuit units may be not corresponding. For example, a plurality of normal sub-pixels of the first display area are normally arranged with a conventional spacing, while a part of the first circuit units of the first display area are compactly arranged with a small spacing, leaving arrangement space for the second circuit units. The positions of the sub-pixels of the first display area and the first circuit units are not corresponding. Generally, the first circuit units and the second circuit units can be arranged in a manner of 3-compression-1 or 4-compression-1 in the transverse direction, that is, three or four first circuit units in the transverse direction are compressed to leave a place where a second circuit unit can be arranged. In another example, a plurality of functional sub-pixels are arranged in the second display area, and the second circuit unit is arranged in the second pixel drive area of the first display area. The positions of the sub-pixels of the second display area and the second circuit unit are not corresponding. In an exemplary implementation, the first display area may be referred to as a normal display area, the first pixel drive area may be referred to as a normal pixel drive area, and the second circuit unit may be referred to as a normal circuit unit. When light transmitted through the second display area is received by a camera apparatus, the second display area may be referred to as a camera display area, the functional sub-pixel may be referred to as a camera sub-pixel, the second pixel drive area may be referred to as a camera pixel drive area, and the second circuit unit may be referred to as a camera circuit unit.

FIG. 6 is a schematic diagram of a sectional structure of a first display area in a display substrate, illustrating the structures of three first circuit units in a first substrate structure layer and three normal sub-pixels in a first light emitting structure layer. As shown in FIG. 6, in a plane perpendicular to the display substrate, a first display area of the display substrate may include a first substrate structure layer 102 disposed on the base substrate 101, a first light emitting structure layer 103 disposed on a side of the first substrate structure layer 102 away from the base substrate, and a first encapsulation structure layer 104 disposed on a side of the first light emitting structure layer 103 away from the base substrate. In some possible implementations, the display substrate may include other film layers, such as a touch structure layer or the like, and the base substrate 101 may be a flexible base substrate or may be a rigid base substrate, and the present disclosure is not limited herein.

In an exemplary implementation, the first substrate structure layer 102 may include a plurality of first circuit units and at least one second circuit unit, the first circuit unit includes a first pixel drive circuit, and the second circuit unit includes a second pixel drive circuit. The first pixel drive circuit and the second pixel drive circuit may include a plurality of transistors and storage capacitors, and FIG. 6 is illustrated by taking only one transistor 210 and one storage capacitor 211 in the first pixel drive circuit as an example.

In an exemplary implementation, the first light emitting structure layer 103 may include a plurality of normal sub-pixels, each normal sub-pixel may include a first light emitting device, the first light emitting device may include at least a first anode 301, a pixel definition layer, an organic light emitting layer, and a cathode, the first anode 301 is connected to a first pixel drive circuit of the first circuit unit in the first display area through a via, the organic light emitting layer is connected to the anode, and the cathode is connected to the organic light emitting layer, and the organic light emitting layer emits light of corresponding color under drive of the first anode and the cathode. The first encapsulation structure layer 104 may include a first encapsulation layer, a second encapsulation layer, and a third encapsulation layer that are stacked. The first encapsulation layer and the third encapsulation layer may be made of an inorganic material, the second encapsulation layer may be made of an organic material, and the second encapsulation layer is disposed between the first encapsulation layer and the third encapsulation layer, which may ensure that external water vapor cannot enter the first light emitting structure layer 103.

FIG. 7 is a schematic diagram of a sectional structure of a second display area in a display substrate, illustrating the structures of a second substrate structure layer and three functional sub-pixels in a second light emitting structure layer. As shown in FIG. 7, in a plane perpendicular to the display substrate, a second display area of the display substrate may include a second substrate structure layer 202 disposed on the base substrate 101, a second light emitting structure layer 203 disposed on a side of the second substrate structure layer 202 away from the base substrate, and a second encapsulation structure layer 204 disposed on a side of the second light emitting structure layer 203 away from the base substrate.

In an exemplary implementation, the second substrate structure layer 202 may include a plurality of stacked insulation layers, and no corresponding pixel drive circuit is provided in the second substrate structure layer 202. In an exemplary implementation, the second light emitting structure layer 203 may include a plurality of functional sub-pixels, each functional sub-pixel may include a second light emitting device, the second light emitting device may include at least a second anode 302, a pixel definition layer, an organic light emitting layer, and a cathode, the second anode 302 is connected to a second pixel drive circuit of the second circuit unit in the first display area through an anode connection line, and the structures of the organic light emitting layer, the cathode and the second encapsulation structure layer 204 in the second display area are substantially the same as those of the organic light emitting layer, the cathode and the first encapsulation structure layer 104 in the first display area.

In an exemplary implementation, the organic light emitting layer may include an emitting layer (EML), and any one or more of following layers: a hole injection layer (HIL), a hole transport layer (HTL), an electron block layer (EBL), a hole block layer (HBL), an electron transport layer (ETL), and an electron injection layer (EIL). In an exemplary implementation, one or more layers of hole injection layers, hole transport layers, electron block layers, hole block layers, electron transport layers, and electron injection layers of all sub-pixels may be a common layer communicated together. Emitting layers of adjacent sub-pixels may be overlapped slightly, or may be mutually isolated.

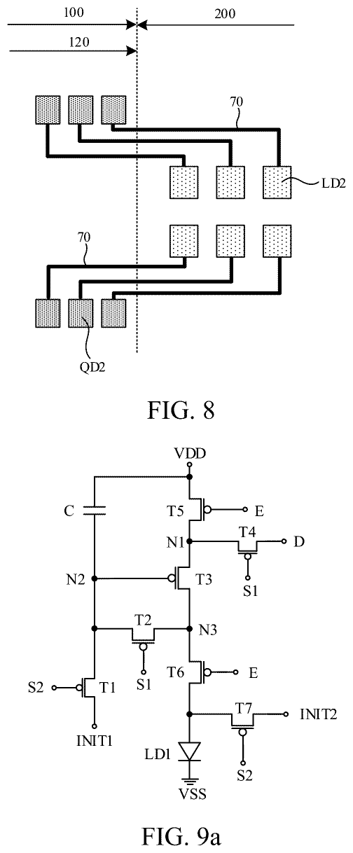

FIG. 8 is a schematic diagram showing a connection between a pixel drive circuit and a light emitting device. As shown in FIGS. 5 and 8, in an exemplary implementation, in a plane parallel to the display substrate, the display substrate may include a first display area 100 and a second display area 200, the first display area 100 may include at least a second pixel drive area 120 close to a side of the second display area 200, the second pixel drive area 120 may include at least one second circuit unit QD2, and the second circuit unit QD2 may include a second pixel drive circuit. The second display area 200 may include a plurality of second light emitting devices LD2, and at least one second light emitting device LD2 is connected to a second pixel drive circuit of at least one second circuit unit QD2 in the first display area 100 through an anode connection line 70.

In an exemplary implementation, only the second light emitting device LD2 is provided in the second display area 200, and no pixel drive circuit for driving the second light emitting device LD2 is provided, so that the second display area 200 can both display and transmit light.

In an exemplary implementation, the second light emitting device LD2 may include at least a second anode, and the second pixel drive circuit of the second circuit unit QD2 is connected to the second anode of the second light emitting device LD2 through an anode connection line 70.

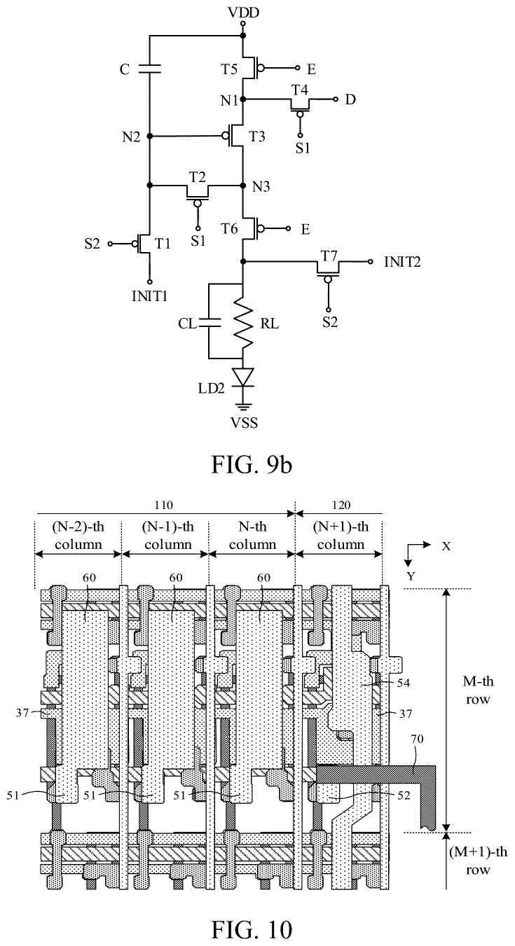

FIG. 9a is an equivalent circuit diagram of a first pixel drive circuit. In an exemplary implementation, the first pixel drive circuit may have a structure of 3TIC, 4TIC, 5TIC, 5T2C, 6TIC, 7TIC or 8TIC. As shown in FIG. 9a, the first pixel drive circuit may include seven transistors (a first transistor T1 to a seventh transistor T7), one memory capacitor C, and the first pixel drive circuit is respectively connected with eight signal lines (a data signal line D, a first scan signal line S1, a first scan signal line S2, a light emitting signal line E, a first initial signal line INIT1, a second initial signal line INIT1, a first power supply line VDD, and a second power supply line VSS).

In an exemplary implementation, the first pixel drive circuit may include a first node N1, a second node N2, and a third node N3. Herein, the first node N1 is respectively connected with a first electrode of the third transistor T3, a second electrode of the fourth transistor T4, and a second electrode of the fifth transistor T5, the second node N2 is respectively connected with a second electrode of the first transistor T1, a control electrode of the third transistor T3, and a second terminal of the storage capacitor C, and the third node N3 is respectively connected with a second electrode of the second transistor T2, a second electrode of the third transistor T3, and a first electrode of the sixth transistor T6.

In an exemplary implementation, a first terminal of the storage capacitor C is connected with the first power supply line VDD, and the second terminal of the storage capacitor C is connected with the second node N2, i.e., the second terminal of the storage capacitor C is connected with the control electrode of the third transistor T3.

In some exemplary embodiments, a control electrode of the first transistor T1 is connected with the second scan signal line S2, a first electrode of the first transistor T1 is connected with the first initial signal line INIT1, and a second electrode of the first transistor T1 is connected with a second node N2. When a turned-on scan signal is applied to the second scan signal line S2, the first transistor T1 transmits a first initialization voltage to the second end of the storage capacitor C to initialize the storage capacitor C.

In an exemplary implementation, a control electrode of the second transistor T2 is connected with the first scan signal line S1, a first electrode of the second transistor T2 is connected with the second electrode of the first transistor T1, and the second electrode of the second transistor T2 is connected with the third node N3. The second transistor T2 enables the control electrode of the third transistor T3 to be connected to the second electrode of the third transistor T3 when a turned-on scan signal is applied to the first scan signal line S1.

In an exemplary implementation, the control electrode of the third transistor T3 is connected with the second node N2, namely the control electrode of the third transistor T3 is connected with the second terminal of the storage capacitor C, a first electrode of the third transistor T3 is connected with a first node N1, and the second electrode of the third transistor T3 is connected with the third node N3. The third transistor T3 may be referred to as a drive transistor, and the third transistor T3 determines a magnitude of a driving current flowing between the first power supply line VDD and the first light emitting device LD1 according to a potential difference between the control electrode and first electrode of the third transistor T3.

In an exemplary implementation, a control electrode of the fourth transistor T4 is connected with the first scan signal line S1, a first electrode of the fourth transistor T4 is connected with the data signal line D, and a second electrode of the fourth transistor T4 is connected with the first node N1. The fourth transistor T4 causes the data voltage of the data signal line D to be inputted to the first node N1 when a turned-on scan signal is applied to the first scan signal line S1.

In an exemplary implementation, a control electrode of the fifth transistor T5 is connected with the light emitting signal line E, a first electrode of the fifth transistor T5 is connected with the first power supply line VDD, and a second electrode of the fifth transistor T5 is connected with the first node N1. A control electrode of the sixth transistor T6 is connected to the light emitting signal line E, the first electrode of the sixth transistor T6 is connected to the third node N3, and a second electrode of the sixth transistor T6 is connected to a first electrode of the first light emitting device LD1. The fifth transistor T5 and the sixth transistor T6 cause the first light emitting device LD1 to emit light by forming a driving current path between the first power supply line VDD and the first light emitting device LD1 when a turned-on light emitting signal is applied to the light emitting signal line E.

In an exemplary implementation, a control electrode of the seventh transistor T7 is connected with the second scan signal line S2, a first electrode of the seventh transistor T7 is connected with the second initial signal line INIT2, and a second electrode of the seventh transistor T7 is connected with the first electrode of the first light emitting device LD1. When a turned-on scan signal is applied to the second scan signal line S2, the seventh transistor T7 transmits a second initial voltage to a first electrode of the first light emitting device LD1 to initialize or release a charge amount accumulated in the first electrode of the first light emitting device LD1.

In an exemplary implementation, the first light emitting device LD1 may be an OLED including a first anode, an organic light emitting layer, and a cathode which are stacked, or may be a QLED including a first anode, a quantum dot layer, and a cathode which are stacked.

In an exemplary implementation, a second electrode of the first light emitting device LD1 is connected with the second power supply line VSS, a signal of the second power supply line VSS is a low-level signal, and a signal of the first power supply line VDD is a high-level signal continuously provided.

In an exemplary implementation, the first transistor T1 to the seventh transistor T7 may be P-type transistors or N-type transistors. Use of a same type of transistors in a first pixel drive circuit may simplify a process flow, reduce process difficulties of a display panel, and improve a product yield. In some possible implementations, the first transistor T1 to the seventh transistor T7 may include a P-type transistor and an N-type transistor.

In an exemplary implementation, the first transistor T1 to the seventh transistor T7 may be low temperature poly-silicon transistors, or may be oxide transistors, or may be low temperature poly-silicon transistors and metal oxide transistors. An active layer of a low temperature poly silicon transistor may be made of Low Temperature Poly Silicon (LTPS for short), and an active layer of a metal oxide transistor may be made of a metal oxide semiconductor (Oxide). The low temperature poly-silicon transistor has advantages such as high migration rate and fast charging. The oxide transistor has advantages such as low leakage current. The low temperature poly-silicon transistor and the metal oxide transistor are integrated on a display substrate to form a Low Temperature Polycrystalline Oxide (LTPO for short) display substrate, so that advantages of the low temperature poly-silicon transistor and the metal oxide transistor can be utilized, low-frequency drive can be achieved, power consumption can be reduced, and display quality can be improved.

In an exemplary implementation, taking a case in which the first transistor T1 to the seventh transistor T7 are all P-type transistors as an example, the operation process of the first pixel drive circuit may include following stages.

In a first stage A1, referred to as a reset stage, the signal of the second scan signal line S2 is a turned-on signal, and the signals of the first scan signal line S1 and the light emitting signal line E are turned-off signals. The turned-on signal of the second scan signal line S2 turns on the first transistor T1, and the signal of the first initial signal line INIT1 is supplied to the second node N2 through the first transistor T1 to initialize (reset) the storage capacitor C and clear an original charge in the storage capacitor. The turned-on signal of the second scan signal line S2 turns on the seventh transistor T7, and the signal of the second initial signal line INIT2 is supplied to the first electrode of the OLED through the seventh transistor T7, to initialize (reset) the first electrode of the first light emitting device LD1, and clear a pre-stored voltage inside the first light emitting device LD1, and initialization is completed. The turned-off signals of the first scan signal line S1 and the light emitting signal line E turn off the second transistor T2, the fourth transistor T4, the fifth transistor T5 and the sixth transistor T6, and the first light emitting device LD1 does not emit light in this stage.

In a second stage A2, referred to as a data writing stage or a threshold compensation stage, the signal of the first scan signal line S1 is a turned-on signal, the signals of the second scan signal line S2 and the light emitting signal line E are turned-off signals, and the data signal line D outputs a data voltage. In this stage, a second terminal of the storage capacitor C is at a low level, so the third transistor T3 is turned on. The turned-on signal of the first scan signal line S1 turns on the second transistor T2 and the fourth transistor T4, the data voltage output by the data signal line D is provided to the second node N2 through a first node N1, the turned-on third transistor T3, a third node N3, and the turned-on second transistor T2, and the storage capacitor C is charged with a difference between the data voltage output by the data signal line D and a threshold voltage of the third transistor T3. A voltage at the second terminal (the second node N2) of the storage capacitor C is Vd−|Vth|, wherein Vd is the data voltage output by the data signal line D, and Vth is the threshold voltage of the third transistor T3. The turned-off signal of the second scan signal line S2 turns off the first transistor T1 and the seventh transistor T7, and the turned-off signal of the light emitting signal line E turns off the fifth transistor T5 and the sixth transistor T6.

In a third stage A3, referred to as a light emitting stage, the signal of the light emitting signal line E is a turned-on signal, and the signals of the first scan signal line S1 and the second scan signal line S2 are turned-off signals. The turned-on signal of the light emitting signal line E turns on the fifth transistor T5 and the sixth transistor T6, and the power supply voltage output by the first power supply line VDD supplies a driving voltage to the first electrode of the first light emitting device LD1 through the turned-on fifth transistor T5, the third transistor T3 and the sixth transistor T6 to drive the first light emitting device LD1 to emit light.

In a drive process of the pixel drive circuit, a drive current flowing through the third transistor T3 (drive transistor) is determined by a voltage difference between a gate electrode and a first electrode of the third transistor T3. The voltage of the second node N2 is Vdata−|Vth|, so the drive current of the third transistor T3 is as follows.

$$I = K * {( Vgs - Vth )}^{2} = K * {[ ( Vdd - Vd + \vert Vth \vert ) - Vth ]}^{2} = K * {[ ( Vdd ‐ Vd ) ]}^{2}$$

Herein, I is the drive current flowing through the third transistor T3, i.e., a drive current for driving the first light emitting device LD1, K is a constant, Vgs is the voltage difference between the gate electrode and the first electrode of the third transistor T3, Vth is the threshold voltage of the third transistor T3, Vd is the data voltage output by the data signal line D, and Vdd is the power voltage output by the first power supply line VDD.

FIG. 9b is an equivalent circuit diagram of a second pixel drive circuit. As shown in FIG. 9b, the equivalent circuit of the second pixel drive circuit is substantially the same as the equivalent circuit of the first pixel drive circuit in the main body, except that the second electrode of the sixth transistor T6 (also the second electrode of the seventh transistor T7) is connected with a first electrode of the second light emitting device LD2 through an anode connection line, the anode connection line forms a connection resistor RL and a connection capacitor CL of a parallel structure.

In an exemplary implementation, as can be seen from comparing the first pixel drive circuit shown in FIG. 9a and the second pixel drive circuit shown in FIG. 9b, the second electrode of the sixth transistor T6 in the first pixel drive circuit is directly connected with the first light emitting device LD1, the second electrode of the sixth transistor T6 in the second pixel drive circuit is connected with the second light emitting device LD2 through an anode connection line of a conductive material, therefore, relative to the first pixel drive circuit, the second pixel drive circuit is added with a connection resistor RL, which is the resistor of the anode connection line, and is added with a connection capacitor CL, which is the capacitor formed by the anode connection line and other conductive layers in the region through which the anode connection line passes. Research shows that, because the connection structure of the first light emitting device and the first pixel drive circuit is different from the connection structure of the second light emitting device and the second pixel drive circuit, therefore, when the data signal line outputs a same data voltage, the brightness of the first light emitting device in the first display area and the second light emitting device in the second display area are different, so that there is a display difference between the first display area and the second display area.

Exemplary embodiments of the present disclosure provide a display substrate, including a first display area and a second display area, the first display area at least partially surrounds the second display area, the first display area is configured to perform image display and includes a plurality of first light emitting devices, a plurality of first circuit units and at least one second circuit unit, the second display area is configured to perform image display and transmit light and includes a plurality of second light emitting devices; the first circuit unit includes a first pixel drive circuit, the first pixel drive circuit includes at least a first anode electrode connected with the first light emitting device and a compensation capacitor plate connected with the first anode electrode, the compensation capacitor plate is configured to form a compensation capacitor; the second circuit unit includes a second pixel drive circuit, the second pixel drive circuit at least includes a second anode electrode, and the second anode electrode is connected with the second light emitting device through an anode connection line.

In an exemplary implementation, the first anode electrode, the second anode electrode, and the compensation capacitor plate are arranged in the same layer.

In an exemplary implementation, at least one second circuit unit includes a power connection line extending along a first direction and a first power supply line extending along a second direction, the first power supply line is connected with the power connection line through a via, the first direction and the second direction intersect.

In an exemplary implementation, the first circuit unit and the second circuit unit each include a storage capacitor, the storage capacitor includes a first plate and a second plate, the orthographic projection of the second plate on a base substrate at least partially overlaps the orthographic projection of the first plate on the base substrate; the second plate of the first circuit unit is connected with the second plate of the first circuit unit adjacent in the first direction through a plate connection line to form the power connection line, alternatively, the second plate of the first circuit unit is connected with the second plate of the second circuit unit adjacent in the first direction through a plate connection line to form the power connection line, alternatively, the second plate of the second circuit unit is connected with the second plate of the second circuit unit adjacent in the first direction through a plate connection line to form the power connection line.

In an exemplary implementation, the orthographic projection of the compensation capacitor plate on the base substrate at least partially overlaps the orthographic projection of the second plate of the first circuit unit on the base substrate.

In an exemplary implementation, the first pixel drive circuit and the second pixel drive circuit each further includes a first transistor as a reset transistor, a second transistor as a compensation transistor, and a third transistor as a drive transistor, a gate electrode of the first transistor is connected with a second scan signal line, a first electrode of the first transistor is connected with a first initial signal line, a second electrode of the first transistor is connected with a first electrode of the second transistor and a gate electrode of the third transistor, respectively, a gate electrode of the second transistor is connected with a first scan signal line, and a second electrode of the second transistor is connected with a second electrode of the third transistor; the orthographic projection of the compensation capacitor plate on the base substrate at least partially overlaps the orthographic projection of the second electrode of the first transistor of the first pixel drive circuit on the base substrate.

In an exemplary implementation, the orthographic projection of the compensation capacitor plate on the base substrate at least partially overlaps the orthographic projection of the first electrode of the first transistor of the first pixel drive circuit on the base substrate.

In an exemplary implementation, the first pixel drive circuit and the second pixel drive circuit each further includes a shield electrode connected to the first initial signal line, and the orthographic projection of the compensation capacitor plate on the base substrate at least partially overlaps the orthographic projection of the shield electrode of the first pixel drive circuit on the base substrate.

In an exemplary implementation, in a plane perpendicular to the display substrate, the first display area includes a first substrate structure layer disposed on a base substrate and a first light emitting structure layer disposed on a side of the first substrate structure layer away from the base substrate, the first substrate structure layer includes a plurality of first circuit units and at least one second circuit unit, and the first light emitting structure layer includes a plurality of first light emitting devices; the second display area includes a second substrate structure layer disposed on the base substrate and a second light emitting structure layer disposed on a side of the second substrate structure layer away from the base substrate, the second substrate structure layer includes a plurality of insulation layers, and the second light emitting structure layer includes a plurality of second light emitting devices.

In an exemplary implementation, the first substrate structure layer includes a first conductive layer, a second conductive layer, a third conductive layer and a fourth conductive layer provided sequentially on the base substrate, the first conductive layer includes gate electrodes of a plurality of transistors in the first pixel drive circuit and the second pixel drive circuit and a first plate of a storage capacitor, the second conductive layer includes a second plate of the storage capacitor, the third conductive layer includes first electrodes and second electrodes of the plurality of transistors, and the fourth conductive layer includes the first anode electrode, the second anode electrode and the compensation capacitor plate.

FIG. 10 is a schematic diagram of a planar structure of a display substrate according to an exemplary embodiment of the present disclosure, illustrating pixel drive circuits of three first circuit units in a first pixel drive area and one second circuit unit in a second pixel drive area. In an exemplary implementation, in a plane parallel to the display substrate, the first display area may include a first pixel drive area 110 and a second pixel drive area 120, the first pixel drive area 110 may include a plurality of first circuit units, the second pixel drive area 120 may include a plurality of second circuit units, a plurality of first circuit units or second circuit units arranged sequentially along a first direction X may be referred to as a unit row, a plurality of first circuit units or second circuit units arranged sequentially along a second direction Y may be referred to as a unit column, and a plurality of unit rows and a plurality of unit columns form an array of circuit units arranged in an array, the first direction X intersects the second direction Y.

As shown in FIG. 10, the first circuit unit of the first pixel drive area 110 may include at least a first pixel drive circuit which may include at least a first anode electrode 51 configured to be connected with a first light emitting device in the first display area and a compensation capacitor plate 60 connected with the first anode electrode 51. The second circuit unit of the second pixel drive area 120 may include at least a second pixel drive circuit which may include at least a second anode electrode 52 configured to be connected with a second light emitting device in the second display area through an anode connection line 70.

In an exemplary implementation, the first anode electrode 51, the second anode electrode 52, and the compensation capacitor plate 60 may be arranged in the same layer and formed synchronously through the same patterning process.

In an exemplary implementation, the first anode electrode 51 and the compensation capacitor plate 60 may be interconnected to be of an integral structure.

In an exemplary implementation, the second pixel drive area 120 may be close to the second display area, and the first pixel drive area 110 may be located on a side of the second pixel drive area 120 away from the second display area, i.e., the first circuit unit may be located on a side of the second circuit unit away from the second display area.

In an exemplary implementation, the first pixel drive circuit and the second pixel drive circuit may each include a storage capacitor, the storage capacitor may include at least a first plate and a second plate, the orthographic projection of the second plate on the display substrate plane at least partially overlaps the orthographic projection of the first plate on the display substrate plane. The second plate of the first pixel drive circuit and the second plate of the first pixel drive circuit adjacent in the first direction X may be connected to each other through a plate connection line, alternatively, the second plate of the first pixel drive circuit and the second plate of the second pixel drive circuit adjacent in the first direction X may be connected to each other through a plate connection line, alternatively, the second plate of the second pixel drive circuit and the second plate of the second pixel drive circuit adjacent in the first direction X may be connected to each other by a plate connection line to form a power connection line 37 extending along the first direction X.

In an exemplary implementation, the second circuit unit of the second pixel drive area 120 may include a first power supply line 54 extending along the second direction Y, which may be connected to the second plate of the second circuit unit through a via, and the first power supply line 54 extending along the second direction Y is connected to a power connection line 37 extending along the first direction X to form a grid-like power supply wiring.

In an exemplary implementation, the first circuit unit of the first pixel drive area 110 is not provided with a first power supply line extending along the second direction Y but only with a power connection line 37 extending along the first direction X.

In an exemplary implementation, the first power supply line 54 may be disposed in the same layer as the first anode electrode 51, the second anode electrode 52 and the compensation capacitor plate 60 and formed synchronously through the same patterning process.

In an exemplary implementation, the orthographic projection of the compensation capacitor plate 60 of the first pixel drive circuit on the base substrate at least partially overlaps the orthographic projection of the second plate of the first pixel drive circuit on the base substrate.

In an exemplary implementation, the second anode electrode 52 of the second pixel drive circuit is connected with the anode connection line 70 through a via.

In an exemplary implementation, in a plane perpendicular to the display substrate, the first display area may include a first substrate structure layer disposed on the base substrate and a first light emitting structure layer disposed on a side of the first substrate structure layer away from the base substrate. The first substrate structure layer may include a first conductive layer, a second conductive layer, a third conductive layer and a fourth conductive layer arranged sequentially on the base substrate, an insulation layer is provided between the first conductive layer and the second conductive layer, between the second conductive layer and the third conductive layer, and between the third conductive layer and the fourth conductive layer, the first conductive layer may include gate electrodes of a plurality of transistors and first plates of storage capacitors in the first pixel drive circuit and the second pixel drive circuit, the second conductive layer may include a second plate of the storage capacitor, the third conductive layer may include first and second electrodes of the plurality of transistors, and the fourth conductive layer may include a first anode electrode 51 and a second anode electrode 52.

In an exemplary implementation, the compensation capacitor plate 60 may be disposed in the fourth conductive layer.

In an exemplary implementation, the first power supply line 54 may be disposed in the fourth conductive layer.

In an exemplary implementation, the first light emitting structure layer may include a plurality of first light emitting devices, the first light emitting device may include at least a first anode, and the first anode electrode 51 is connected with the first anode of the first light emitting device through a via.

In an exemplary implementation, the second display area may include a second substrate structure layer disposed on the base substrate and a second light emitting structure layer disposed on a side of the second substrate structure layer away from the base substrate. The second substrate structure layer may include a plurality of insulation layers stacked, the second light emitting structure layer may include a plurality of second light emitting devices, the second light emitting device may include at least a second anode, the second anode electrode 52 is connected with a first end of the anode connection line 70 through a via, and a second end of the anode connection line 70, after extending to the second display area, is connected with the second anode of the second light emitting device.

Exemplary description is made below through a preparation process of a display substrate. A “patterning process” mentioned in the present disclosure includes coating with a photoresist, mask exposure, development, etching, photoresist stripping, and other treatments for a metal material, an inorganic material, or a transparent conductive material, and includes coating with an organic material, mask exposure, development, and other treatments for an organic material. Deposition may be any one or more of sputtering, evaporation, and chemical vapor deposition. Coating may be any one or more of spray coating, spin coating, and ink-jet printing. Etching may be any one or more of dry etching and wet etching, which is not limited in present disclosure. A “thin film” refers to a layer of thin film made of a material on a base substrate through a process such as deposition, coating, etc. If the “thin film” does not need a patterning process in an entire preparation process, the “thin film” may also be called a “layer”. If the “thin film” needs a patterning process in an entire preparation process, it is called a “thin film” before the patterning process, and called a “layer” after the patterning process. The “layer” after the patterning process includes at least one “pattern”. “A and B being disposed on a same layer” mentioned in the present disclosure means that A and B are formed simultaneously through a same patterning process, and a “thickness” of a film layer is a dimension of the film layer in a direction perpendicular to a display substrate. In an exemplary embodiment of the present disclosure, “the orthographic projection of B is within a range of the orthographic projection of A” or “the orthographic projection of A includes the orthographic projection of B” refers to that a boundary of the orthographic projection of B falls within a range of a boundary of the orthographic projection of A, or the boundary of the orthographic projection of A is overlapped with the boundary of the orthographic projection of B.

In an exemplary implementation, taking three first circuit units of the first pixel drive area 110 and one second circuit unit of the second pixel drive area 120 as an example, a preparation process of a display substrate may include following operations. Herein, a (N−2)-th unit column, a (N−1)-th unit column and a N-th unit column in a M-th unit row are first circuit units including the first pixel drive circuit, and a (N+1)-th unit column in the M-th unit row are second circuit units including the second pixel drive circuit.

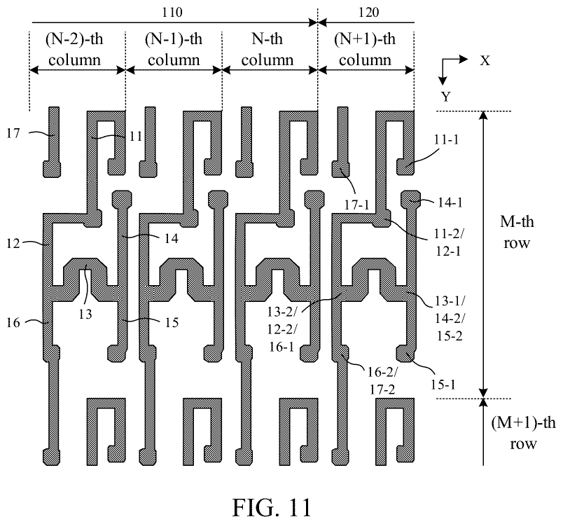

(1) Forming a pattern of a semiconductor layer. In an exemplary implementation, forming a pattern of a semiconductor layer may include: depositing sequentially a first insulating thin film and a semiconductor thin film on a base substrate, and patterning the semiconductor thin film through a patterning process to form a first insulation layer overlying the base substrate and a semiconductor layer disposed on the first insulation layer, as shown in FIG. 11.

In an exemplary implementation, the semiconductor layer of each first circuit unit and each second circuit unit may include at least a first active layer 11 of a first transistor T1 to a seventh active layer 17 of a seventh transistor T7. The first active layer 11 to the seventh active layer 17 are connected with each other in an integrated structure, and in each unit column, a sixth active layer 16 of a circuit unit in a M-th row and a seventh active layer 17 of a circuit unit in a (M+1)-th row are connected with each other, that is, the semiconductor layers of adjacent circuit units in each unit column are connected with each other in an integrated structure.

In an exemplary implementation, a fourth active layer 14 and a fifth active layer 15 may be located on a side of a third active layer 13 of the circuit unit in the first direction X, and a second active layer 12 and a sixth active layer 16 may be located on a side of the third active layer 13 of the circuit unit in an opposite direction of the first direction X. The first active layer 11, the second active layer 12, the fourth active layer 14 and the seventh active layer 17 in the M-th row circuit unit may be located at a side of the third active layer 13 of the circuit unit away from the (M+1) th circuit unit row, the first active layer 11 and the seventh active layer 17 may be located at a side of the second active layer 12 and the fourth active layer 14 away from the third active layer 13, and the fifth active layer 15 and the sixth active layer 16 in the M-th row circuit unit are located at a side of the third active layer 13 close to the (M+1)th row circuit unit.

In an exemplary implementation, the first active layer 11 may be in an “n” shape, the second active layer 12 may be in a “L” shape, the third active layer 13 may be in an “Ω” shape, the fourth active layer 14, the fifth active layer 15, the sixth active layer 16 and the seventh active layer 17 may be in an “I” shape.

In an exemplary implementation, an active layer of each transistor may include a first area, a second area, and a channel region located between the first area and the second area. In an exemplary implementation, a first area 11-1 of the first active layer 11, a first area 14-1 of the fourth active layer 14, a first area 15-1 of the fifth active layer 15 and a first area 17-1 of the seventh active layer 17 may be individually provided. A second area 11-2 of the first active layer 11 may also serve as a first area 12-1 of the second active layer 12; a first area 13-1 of the third active layer 13 may also serve as a second area 14-2 of the fourth active layer 14 and a second area 15-2 of the fifth active layer 15; a second area 13-2 of the third active layer 13 may also serve as a second area 12-2 of the second active layer 12 and a first area 16-1 of the sixth active layer 16; a second area 16-2 of the sixth active layer 16 may also serve as a second area 17-2 of the seventh active layer 17.

In an exemplary implementation, the pattern of the semiconductor layer of the first circuit unit in the first pixel drive area and the pattern of the semiconductor layer of the second circuit unit in the second pixel drive area may be substantially the same.

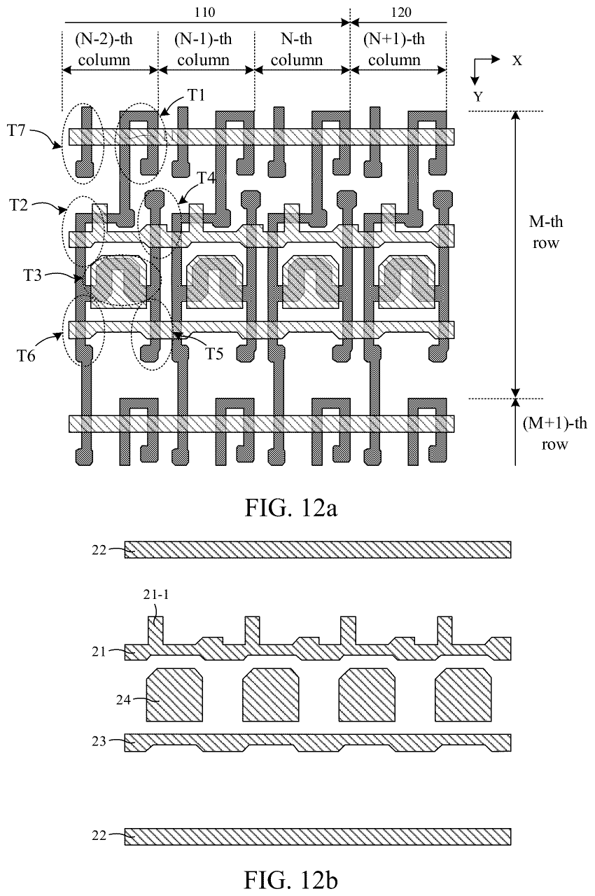

(2) Forming a pattern of a first conductive layer. In an exemplary implementation, forming a pattern of a first conductive layer may include: sequentially depositing a second insulating thin film and a first conductive thin film on the base substrate on which the above-mentioned pattern is formed, and patterning the first conductive thin film through a patterning process to form a second insulation layer that covers a pattern of the semiconductor layer and form a pattern of the first conductive layer disposed on the second insulation layer, as shown in FIG. 12a and FIG. 12b, and FIG. 12b is a planar schematic diagram of the first conductive layer in FIG. 12a. In an exemplary implementation, the first conductive layer may be called a first gate metal (GATE1) layer.

In an exemplary implementation, the pattern of the first conductive layer of each first circuit unit and each second circuit unit may include at least a first scan signal line 21, a second scan signal line 22, a light emitting control line 23, and a first plate 24 of the storage capacitor.

In an exemplary implementation, the first plate 24 of the storage capacitor may be rectangular, rectangle corners may be set with chamfer, and the orthographic projection of the first plate 24 on the base substrate at least partially overlaps the orthographic projection of the third active layer on the base substrate. In an exemplary implementation, the first plate 24 may serve as a first plate of the storage capacitor and a gate electrode of the third transistor T3 simultaneously.

In an exemplary implementation, the first scan signal line 21, the second scan signal line 22 and the light emitting control line 23 may be in a shape of a line with a main body portion extending along the first direction X. The first scan signal line 21 and the second scan signal line 22 in the M-th row circuit unit may be located at a side of the first plate 24 of the present circuit unit away from the (M+1) th row circuit unit, the second scan signal line 22 may be located at a side of the first scan signal line 21 of the present circuit unit away from the first plate 24, and the light emitting control line 23 may be located at a side of the first plate 24 of the present circuit unit close to the (M+1)th row circuit unit.

In an exemplary implementation, the region where the first scan signal line 21 overlaps the second active layer may serve as a gate electrode of the second transistor T2, the first scan signal line 21 is provided with a gate block 21-1 protruding toward the second scan signal line 22, and the orthographic projection of the gate block 21-1 on the base substrate at least partially overlaps the orthographic projection of the second active layer on the base substrate to form the second transistor T2 with a double-gate structure.

In an exemplary implementation, the region where the first scan signal line 21 overlaps the fourth active layer serves as a gate electrode of the fourth transistor T4, the region where the second scan signal line 22 overlaps the first active layer serves as a gate electrode of the first transistor T1 with a double-gate structure, the region where the second scan signal line 22 overlaps the seventh active layer serves as a gate electrode of the seventh transistor T7, the region where the light emitting control line 23 overlaps the fifth active layer serves as a gate electrode of the fifth transistor T5, and the region where the light emitting control line 23 overlaps the sixth active layer serves as a gate electrode of the sixth transistor T6.

In an exemplary implementation, after the pattern of the first conductive layer is formed, the semiconductor layer may be subjected to a conductorization treatment by using the first conductive layer as a shield. A region of the semiconductor layer, which is shielded by the first conductive layer, forms channel regions of the first transistor T1 to the seventh transistor T7, and a region of the semiconductor layer, which is not shielded by the first conductive layer, is made to be conductorized, that is, first areas and second areas of the first active layer to the seventh active layer are all made to be conductorized.

In an exemplary implementation, the pattern of the first conductive layer of the first circuit unit in the first pixel drive area and the pattern of the first conductive layer of the second circuit unit in the second pixel drive area may be substantially the same.

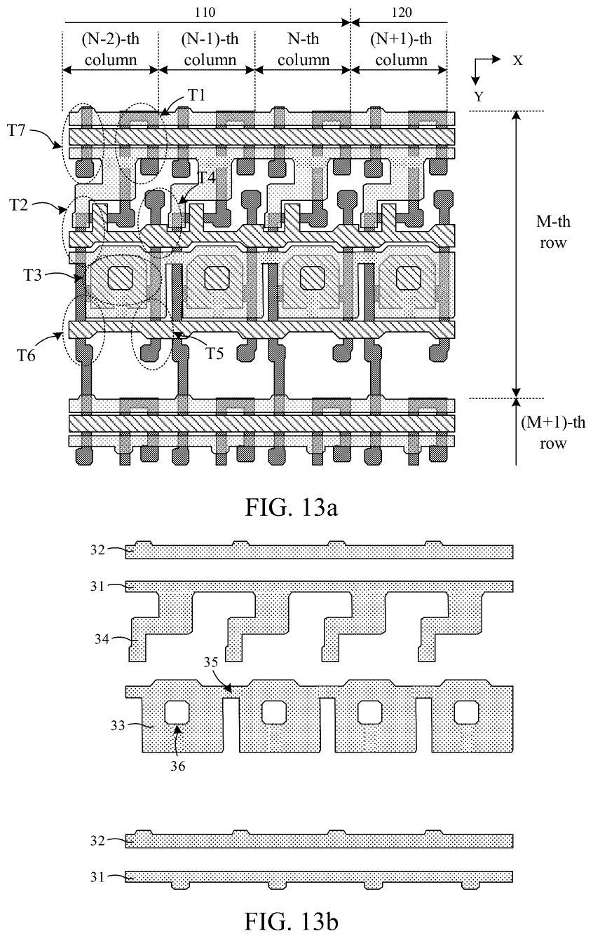

(3) Forming a pattern of a second conductive layer. In an exemplary implementation, forming a pattern of a second conductive layer may include: depositing a third insulating film and a second conductive film sequentially on the base substrate on which the aforementioned patterns are formed, and patterning the second conductive film by a patterning process to form a third insulation layer covering the first conductive layer and the pattern of the second conductive layer disposed on the third insulation layer, as shown in FIGS. 13a and 13b, FIG. 13b is a planar schematic diagram of the second conductive layer in FIG. 13a. In an exemplary implementation, the second conductive layer may be called a second gate metal (GATE 2) layer.

In an exemplary implementation, the pattern of the second conductive layer of each first circuit unit and each second circuit unit includes at least a first initial signal line 31, a second initial signal line 32, a second plate 33 of the storage capacitor, a shield electrode 34, and a plate connection line 35.

In an exemplary implementation, the second plate 33 of the storage capacitor may be located between the first scan signal line 21 and the light emitting control line 23 of the circuit unit, the second plates 33 of adjacent circuit units in the first direction X or in an opposite direction of the first direction X may be connected by the plate connection line 35, a first end of the plate connection line 35 is connected to the second plate 33 of the circuit unit, and a second end of the plate connection line 35, after extending along the first direction X or an opposite direction of the first direction X, is connected to the second plate 33 of the adjacent circuit unit, that is, the plate connection line 35 is configured to connect the second plates 33 of adjacent circuit units on a unit row to each other. In an exemplary implementation, the second plates of a plurality of circuit units in one unit row form an integrated structure connected with each other through the plate connection line 35, and the second plates with the integrated structure may be reused as a power connection line, thus ensuring that a plurality of second plates in one unit row have a same potential, which is beneficial to improving uniformity of the panel, avoiding a poor display of the display substrate and ensuring a display effect of the display substrate.

In an exemplary implementation, the outline of the second plate 33 may be rectangular, rectangle corners may be provided with chamfers, the orthographic projection of the second plate 33 on the base substrate at least partially overlaps the orthographic projection of the first plate 24 on the base substrate, and the first plate 24 and the second plate 33 form the storage capacitor of the pixel drive circuit. The second plate 33 is provided with an opening 36 which may be located in the middle of the second plate 33. The opening 36 may be rectangular, so that the second plate 33 forms an annular structure. The opening 36 exposes the third insulation layer covering the first plate 24, and the orthographic projection of the first plate 24 on the base substrate includes the orthographic projection of the opening 36 on the base substrate. In an exemplary implementation, the opening 36 is configured to accommodate a first via subsequently formed that is located within the opening 36 and exposes the first plate 24, so that a second electrode of a first transistor T1 subsequently formed is connected with the first plate 24 through the first via.

In an exemplary implementation, the first and second initial signal lines 31 and 32 may be in a shape of a line with a main body portion extending along the first direction X, the first initial signal line 31 in a M-th row circuit unit may be located between the first scan signal line 21 and the second scan signal line 22 of the circuit unit, and the second initial signal line 32 may be located on a side of the second scan signal line 22 of the circuit unit away from the first scan signal line 21.

In an exemplary implementation, the shield electrode 34 may be located between the first scan signal line 21 and the first initial signal line 31 of the circuit unit, the shield electrode 34 may be in a shape of a bent line, a first end of the shield electrode 34 is connected to the first initial signal line 31, and a second end of the shield electrode 34 extends in the second direction Y to be close to the first scan signal line 21.

In an exemplary implementation, the first initial signal line 31 and the shield electrode 34 may be interconnected to be of an integral structure.

In an exemplary implementation, the orthographic projection of the shield electrode 34 on the base substrate at least partially overlaps the orthographic projection of the second area of the first active layer on the base substrate, and the orthographic projection of the shield electrode 34 on the base substrate at least partially overlaps the orthographic projection of the second active layer between two gate electrodes in the second transistor T2 on the base substrate. Because the shield electrode 34 is connected to the first initial signal line 31, the shield electrode 34 can shield the influence of data voltage jump on key nodes, avoid the influence of data voltage jump on the potential of key nodes of the pixel driving circuit, and improve the display effect.

In an exemplary implementation, the pattern of the second conductive layer of the first circuit unit in the first pixel drive area and the pattern of the second conductive layer of the second circuit unit in the second pixel drive area may be substantially the same.

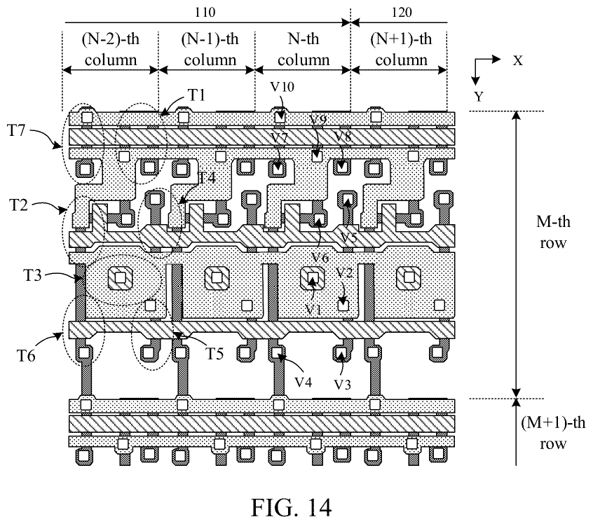

(4) Forming a pattern of a fourth insulation layer. In an exemplary implementation, forming a pattern of a fourth insulation layer may include: depositing a fourth insulating thin film on the base substrate on which the aforementioned patterns are formed, and patterning the fourth insulating thin film by a patterning process, to form a fourth insulation layer covering the second conductive layer, wherein a plurality of vias are provided on the fourth insulation layer, as shown in FIG. 14.

In an exemplary implementation, a plurality of vias of each first circuit unit and each second circuit unit includes at least a first via V1, a second via V2, a third via V3, a fourth via V4, a fifth via V5, a sixth via V6, a seventh via V7, an eleventh via V11, a ninth via V9, and a tenth via V10.

In an exemplary implementation, the orthographic projection of the first via V1 on the base substrate is within a range of the orthographic projection of the opening 36 of the second plate 33 on the base substrate, the fourth insulation layer and the third insulation layer in the first via V1 are etched away to expose a surface of the first plate 24. The first via V1 is configured such that a second electrode of the first transistor T1 subsequently formed is connected with the first plate 24 through the via V1.

In an exemplary implementation, the orthographic projection of the second via V2 on the base substrate is within a range of the orthographic projection of the second plate 33 on the base substrate, the fourth insulation layer in the second via V2 is etched away to expose a surface of the second plate 33, and the second via V2 is configured such that a first electrode of the fifth transistor T5 subsequently formed is connected with the second plate 33 through the via.

In an exemplary implementation, the orthographic projection of the third via V3 on the base substrate is within a range of the orthographic projection of the first area of the fifth active layer on the base substrate. The fourth insulation layer, the third insulation layer and the second insulation layer in the third via V3 are etched away to expose a surface of the first area of the fifth active layer, and the third via V3 is configured such that the first electrode of the fifth transistor T5 formed subsequently is connected with the first area of the fifth active layer through the via V3.

In an exemplary implementation, the orthographic projection of the fourth via V4 on the base substrate is within a range of the orthographic projection of the second area of the sixth active layer on the base substrate, the fourth insulation layer, the third insulation layer and the second insulation layer in the fourth via V4 are etched away to expose a surface of the second area of the sixth active layer (also the second area of the seventh active layer), and the fourth via V4 is configured such that a second electrode of the sixth transistor T6 (the second electrode of the seventh transistor T7) subsequently formed is connected with the second area of the sixth active layer through the via.

In an exemplary implementation, the orthographic projection of the fifth via V5 on the base substrate is within a range of the orthographic projection of the first area of the fourth active layer on the base substrate. The fourth insulation layer, the third insulation layer and the second insulation layer in the fifth via V5 are etched away to expose a surface of the first area of the fourth active layer, and the fifth via V5 is configured such that the first electrode of the fourth transistor T4 formed subsequently is connected with the first area of the fourth active layer through the via V5.

In an exemplary implementation, the orthographic projection of the sixth via V6 on the base substrate is within a range of the orthographic projection of the second area of the first active layer on the base substrate, the fourth insulation layer, the third insulation layer and the second insulation layer in the sixth via V6 are etched away to expose a surface of the second area of the first active layer (which is also the first area of the second active layer), the sixth via V6 is configured such that a second electrode of the first transistor T1 (the first electrode of the second transistor T2) subsequently formed is connected with the second area of the first active layer through the via V6.

In an exemplary implementation, the orthographic projection of the seventh via V7 on the base substrate is located within a range of the orthographic projection of the first area of the seventh active layer on the base substrate. The fourth insulation layer, the third insulation layer and the second insulation layer in the seventh via V7 is etched away to expose a surface of the first area of the seventh active layer. The seventh via V7 is configured such that a first electrode of the seventh transistor T7 subsequently formed is connected with the first area of the seventh active layer through the via V7.

In an exemplary implementation, the orthographic projection of the eighth via V8 on the base substrate is within a range of the orthographic projection of the first area of the first active layer on the base substrate, the fourth insulation layer, the third insulation layer and the second insulation layer in the eighth via V8 are etched away to expose a surface of the first area of the first active layer. The eighth via V8 is configured such that a first electrode of the first transistor T1 subsequently formed is connected with the first area of the first active layer through the via V8.

In an exemplary implementation, the orthographic projection of the ninth via V9 on the base substrate is within a range of the orthographic projection of the first initial signal line 31 on the base substrate, the fourth insulation layer in the ninth via V9 is etched away to expose a surface of the first initial signal line 31. The ninth via V9 is configured such that a first electrode of the first transistor T1 subsequently formed is connected with the first initial signal line 31 through the via V9.

In an exemplary implementation, the orthographic projection of the tenth via V10 on the base substrate is within a range of the orthographic projection of the second initial signal line 32 on the base substrate, the fourth insulation layer in the tenth via V10 is etched away to expose a surface of the second initial signal line 32. The tenth via V10 is configured such that a first electrode of the seventh transistor T7 formed subsequently is connected with the second initial signal line 32 through the via V10.

In an exemplary implementation, patterns of the plurality of vias of the first circuit unit in the first pixel drive area may be substantially the same as patterns of the plurality of via of the second circuit unit in the second pixel drive area.

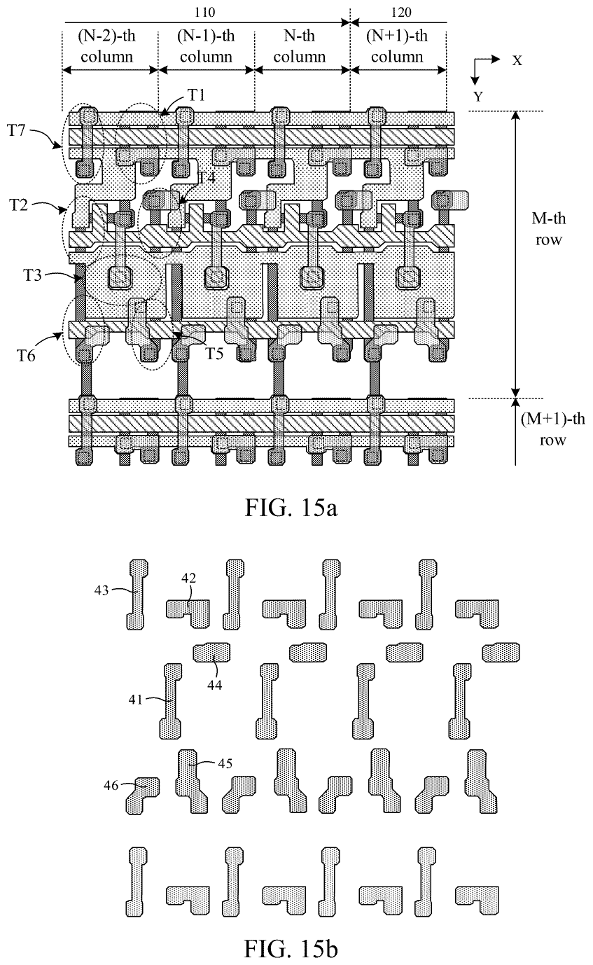

(5) Forming a pattern of a third conductive layer. In an exemplary implementation, forming a third conductive layer may include: depositing a third conductive thin film on the base substrate on which the above-mentioned patterns are formed, and patterning the third conductive thin film through a patterning process to form a third conductive layer disposed on the fourth insulation layer, as shown in FIG. 15a and FIG. 15b, and FIG. 15b is a planar schematic diagram of the third conductive layer in FIG. 15a. In an exemplary implementation, the third conductive layer may be referred to as a first source drain metal (SD1) layer.

In an exemplary implementation, the third conductive layer of each first circuit unit and each second circuit unit includes at least a first connection electrode 41, a second connection electrode 42, a third connection electrode 43, a fourth connection electrode 44, a fifth connection electrode 45, and a sixth connection electrode 46.

In an exemplary implementation, the first connection electrode 41 may be shaped as a strip with a main body portion extending in the second direction Y, a first end of the first connection electrode 41 is connected to the first plate 24 through the first via V1, and a second end of the first connection electrode 41 is connected to the second area of the first active layer (also the first area of the second active layer) through the sixth via V6, so that the first plate 24, a second electrode of the first transistor T1 and a first electrode of the second transistor T2 have the same potential. In an exemplary implementation, the first connection electrode 41 may serve as the second electrode of the first transistor T1 and the first electrode of the second transistor T2 simultaneously.

In an exemplary implementation, the second connection electrode 42 may be shaped in an “L” shape, a first end of the second connection electrode 42 is connected to the first area of the first active layer through the eighth via V8, and a second end of the second connection electrode 42 is connected to the first initial signal line 31 through the ninth via V9. In an exemplary implementation, the second connection electrode 42 may serve as the first electrode of the first transistor T1, which enables the first initial signal line 31 to write a first initial signal into the first transistor T1.

In an exemplary implementation, the third connection electrode 43 may be shaped as a strip with a main body portion extending in the second direction Y, a first end of the third connection electrode 43 is connected to the first area of the seventh active layer through the seventh via V7, and a second end of the third connection electrode 43 is connected to the second initial signal line 32 through the tenth via V10. In an exemplary implementation, the third connection electrode 43 may serve as the first electrode of the seventh transistor T7, which enables the second initial signal line 32 to write a second initial signal into the seventh transistor T7.

In an exemplary implementation, the fourth connection electrode 44 may be rectangular and the fourth connection electrode 44 is connected to the first area of the fourth active layer through the fifth via V5. In an exemplary implementation, the fourth connection electrode 44 may serve as a first electrode of the fourth transistor T4 and the fourth connection electrode 44 is configured to be connected to the data signal line formed subsequently.

In an exemplary implementation, the fifth connection electrode 45 may be shaped as a strip with a main body portion extending in the second direction Y, a first end of the fifth connection electrode 45 is connected to the first area of the fifth active layer through the third via V3, and a second end of the fifth connection electrode 45 is connected to the second plate 33 through the second via V2, so that the second plate 33 and the first area of the fifth active layer have the same potential. In an exemplary implementation, the fifth connection electrode 45 may serve as a first electrode of the fifth transistor T5 and the fifth connection electrode 45 of the second circuit unit is configured to be connected to the first power supply line formed subsequently.

In an exemplary implementation, the sixth connection electrode 46 may be rectangular, and the sixth connection electrode 46 is connected to the second area of the sixth active layer (also the second area of the seventh active layer) through the fourth via V4, so that the second area of the sixth active layer and the second area of the seventh active layer have the same potential. In an exemplary implementation, the sixth connection electrode 46 may serve as a second electrode of the sixth transistor T6 (or a second electrode of the seventh transistor T7), the sixth connection electrode 46 of the first circuit unit is configured to be connected to the first anode electrode formed subsequently, and the sixth connection electrode 46 of the second circuit unit is configured to be connected to the second anode electrode formed subsequently.

In an exemplary implementation, the pattern of the third conductive layer of the first circuit unit in the first pixel drive area and the pattern of the third conductive layer of the second circuit unit in the second pixel drive area may be substantially the same.

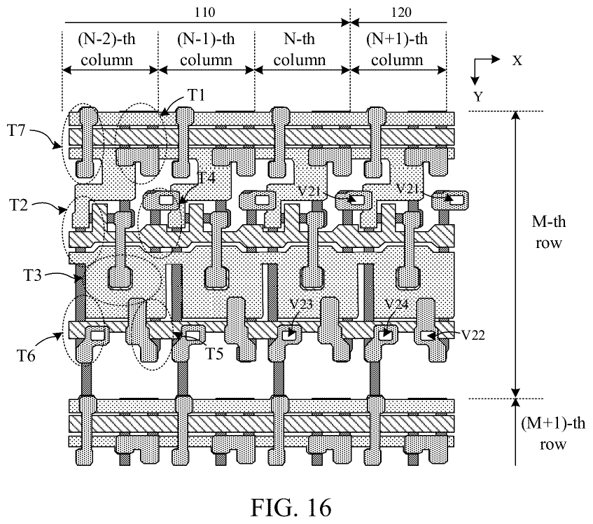

(6) Forming a pattern of a first planarization layer. In an exemplary implementation, forming a pattern of a first planarization layer may include coating a first planarization film on the base substrate on which the above-mentioned patterns are formed, patterning the first planarization film through a patterning process, forming a first planarization layer covering the third conductive layer, the first planarization layer is provided with a plurality of vias, as shown in FIG. 16.

In an exemplary implementation, the plurality of vias of each first circuit unit of the first pixel drive area 110 include at least a twenty-first via V21 and a twenty-third via V23, and the plurality of vias of each second circuit unit of the second pixel drive area 120 include at least a twenty-first via V21, a twenty-second via V22 and a twenty-fourth via V24.

In an exemplary implementation, the twenty-first via V21 may be provided in each first circuit unit of the first pixel drive area 110 and each second circuit unit of the second pixel drive area 120, the orthographic projection of the twenty-first via V21 on the base substrate may be within a range of the orthographic projection of the fourth connection electrode 44 on the base substrate. The first planarization layer in the twenty-first via V21 is removed to expose a surface of the fourth connection electrode 44. The twenty-first via V21 is configured such that a data signal line subsequently formed is connected with the fourth connection electrode 44 through the via V21.

In an exemplary implementation, the twenty-second via V22 may be provided in each second circuit unit of the second pixel drive area 120, the orthographic projection of the twenty-second via V22 on the base substrate may be within a range of the orthographic projection of the fifth connection electrode 45 on the base substrate. The first planarization layer in the twenty-second via V22 is removed to expose a surface of the fifth connection electrode 45. The twenty-second via V22 is configured such that the first power supply line formed subsequently is connected with the fifth connection electrode 45 in the second circuit unit through the via V22. In an exemplary implementation, the twenty-second via V22 is not provided in each first circuit unit of the first pixel drive area 110.

In an exemplary implementation, the twenty-third via V23 may be provided in each first circuit unit of the first pixel drive area 110, the orthographic projection of the twenty-third via V23 on the base substrate may be within a range of the orthographic projection of the sixth connection electrode 46 on the base substrate. The first planarization layer in the twenty-third via V23 is removed to expose a surface of the sixth connection electrode 46. The twenty-third via V23 is configured such that the first anode electrode formed subsequently is connected with the sixth connection electrode 46 in the first circuit unit through the via V23.

In an exemplary implementation, the twenty-fourth via V24 may be provided in each second circuit unit of the second pixel drive area 120, the orthographic projection of the twenty-fourth via V24 on the base substrate may be within a range of the orthographic projection of the sixth connection electrode 46 on the base substrate, the first planarization layer in the twenty-fourth via V24 is removed to expose a surface of the sixth connection electrode 46. The twenty-fourth via V24 is configured such that the second anode electrode formed subsequently is connected with the sixth connection electrode 46 in the second circuit unit through the via V24.

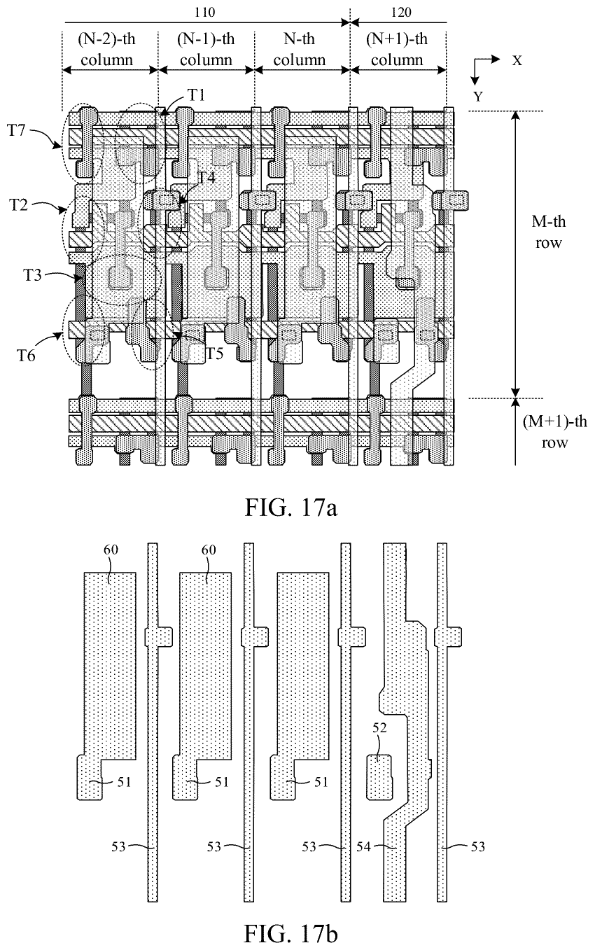

(7) Forming a pattern of a fourth conductive layer. In an exemplary implementation, forming a pattern of a fourth conductive layer may include depositing a fourth conductive film on the base substrate on which the above-mentioned patterns are formed, patterning the fourth conductive film using a patterning process to form a fourth conductive layer disposed on the first planarization layer, as shown in FIGS. 17a and 17b, FIG. 17 is a planar schematic diagram of the fourth conductive layer in FIG. 17a. In an exemplary implementation, the fourth conductive layer may be referred to as a second source drain metal (SD2) layer.

In an exemplary implementation, the fourth conductive layer of each first circuit unit of the first pixel drive area 110 includes at least a first anode electrode 51, a data signal line 53, and a compensation capacitor plate 60, and the fourth conductive layer of each second circuit unit of the second pixel drive area 120 includes at least a second anode electrode 52, a data signal line 53, and a first power supply line 54.

In an exemplary implementation, the first anode electrode 51 may be provided in each first circuit unit of the first pixel drive area 110, and the first anode electrode 51 is connected to the sixth connection electrode 46 in the first circuit unit through the twenty-third via V23. In an exemplary implementation, the first anode electrode 51 is configured to be connected with a first anode of the first light emitting device subsequently formed, because the sixth connection electrode 46 in each first circuit unit is connected with the second area of the sixth active layer (also the second area of the seventh active layer) through a via, thus, the first anode electrode 51 is connected with the second area of the sixth active layer (which is also the second area of the seventh active layer) through the sixth connection electrode 46, thereby achieving the connection between the first anode of the first light emitting device and the second area of the sixth active layer (which is also the second area of the seventh active layer) in the first pixel drive circuit.

In an exemplary implementation, the second anode electrode 52 may be provided in each second circuit unit of the second pixel drive area 120, and the second anode electrode 52 is connected to a sixth connection electrode 46 in the second circuit unit through the twenty-fourth via V24. In an exemplary implementation, the second anode electrode 52 is configured to be connected to the anode connection line formed subsequently, and is connected with the second anode of the second light emitting device in the second display area through the anode connection line, because the sixth connection electrode 4 6 in each second circuit unit is connected with the second area of the sixth active layer (also the second area of the seventh active layer) through a via, thus, the second anode electrode 52 can be connected with the second area of the sixth active layer (also the second area of the seventh active layer) through the sixth connection electrode 46, so that the second anode of the second light emitting device is connected with the second area of the sixth active layer (also the second area of the seventh active layer) in the second pixel drive circuit.

In an exemplary implementation, the first anode electrodes 51 and second anode electrodes 52 may be rectangular, and the size and position of the first anode electrode 51 may be substantially the same as that of the second anode electrode 52.

In an exemplary implementation, the data signal line 53 may be in a shape of a straight line with a main body portion extending along the second direction Y, the data signal line 53 may be provided in each first circuit unit of the first pixel drive area 110 and each second circuit unit of the second pixel drive area 120, and the data signal line 53 is connected with the fourth connection electrode 44 through the twenty-first via V21. Because the fourth connection electrode 44 is connected with the first area of the fourth active layer through a via, it can be achieved that the data signal line 53 writes a data signal into the first electrode of the fourth transistor T4.

In an exemplary implementation, the first power supply line 54 may be provided in the second circuit unit of the second pixel drive area 120 and the first power supply line 54 may not be provided in the first circuit unit of the first pixel drive area 110. The first power supply line 54 may be in a shape of a bent line with a main body portion extending in the second direction Y, and is connected with the fifth connection electrode 45 in the second circuit unit through the twenty-second via V22. Because the fifth connection electrode 45 is simultaneously connected with the second plate 33 and the first area of the fifth active layer through a via, it is achieved that the first power supply line 54 writes a first power supply signal to a first electrode of the fifth transistor T5 and that the second plate 33 and the first electrode of the fifth transistor T5 have the same potential.

In an exemplary implementation, the first power supply line 54 of each second circuit unit can be designed with unequal width, which may not only facilitate the layout of pixel structure, but also reduce the parasitic capacitance generated by the first power supply line.

In an exemplary implementation, the compensation capacitor plate 60 may be rectangular, and may be provided on a side of the first anode electrode 51 in an opposite direction of the second direction Y and connected to the first anode electrode 51.

In an exemplary implementation, the compensation capacitor plate 60 and the first anode electrode 51 may be interconnected to be of an integral structure.

In an exemplary implementation, in at least one first pixel drive circuit, the orthographic projection of the compensation capacitor plate 60 on the base substrate and the orthographic projection of the second plate 33 on the base substrate may at least partially overlap.

In an exemplary implementation, in at least one first pixel drive circuit, the orthographic projection of the compensation capacitor plate 60 on the base substrate at least partially overlaps the orthographic projection of the shield electrode 34 on the base substrate.

In an exemplary implementation, in at least one first pixel drive circuit, the orthographic projection of the compensation capacitor plate 60 on the base substrate at least partially overlaps the orthographic projection of the first connection electrode 41 on the base substrate.

In an exemplary implementation, in at least one first pixel drive circuit, the orthographic projection of the compensation capacitor plate 60 on the base substrate at least partially overlaps the orthographic projection of the second connection electrode 42 on the base substrate.

In an exemplary implementation, in at least one first pixel drive circuit, the orthographic projection of the compensation capacitor plate 60 on the base substrate at least partially overlaps the orthographic projection of the fifth connection electrode 45 on the base substrate.

In an exemplary implementation, because the second plates 33 of adjacent circuit units in one unit row are connected to each other through the plate connection line 35 to form an integral structure, the second plates 33 connected to each other in the unit row can be reused as a power connection line extending along the first direction X (transverse direction). Because the first power supply line 54 of the second circuit unit is connected to the second plate 33 as a power connection line through a via, the power connection line may transmit a first power supply signal to the second plates 33 of all circuit units on the unit row, thus, the second plate 33 of the first circuit unit can transmit the first power supply signal to the first area of the fifth active layer through the fifth connection electrode 45, and writing the first power supply signal to the first electrode of the fifth transistor T5 of the first circuit unit is achieved.

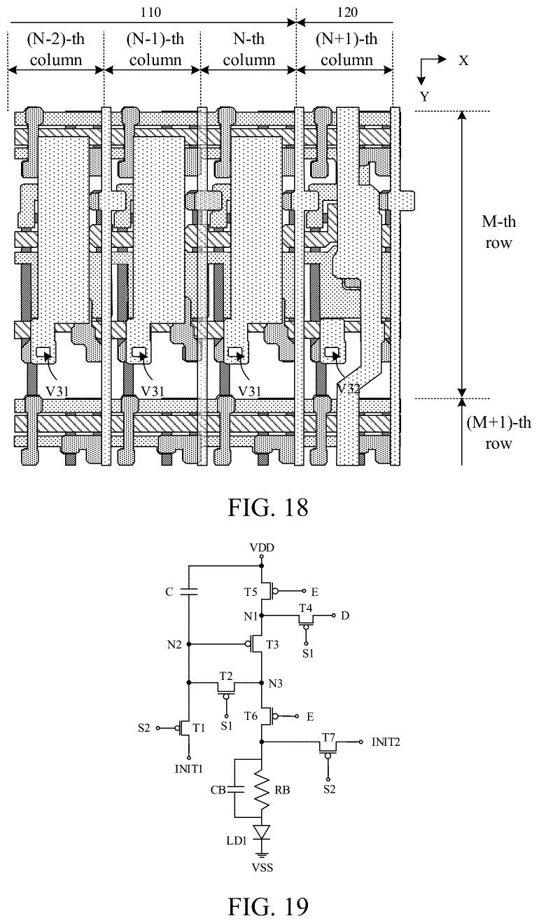

(8) Forming a pattern of a second planarization layer. In an exemplary implementation, forming a pattern of a second planarization layer may include coating a second planarization film on the base substrate on which the above-mentioned patterns are formed, patterning the second planarization film using a patterning process to form the second planarization layer covering the fourth conductive layer, the second planarization layer is provided with a plurality of vias, as shown in FIG. 18.

In an exemplary implementation, the plurality of vias of each first circuit unit includes at least a thirty-first via V31, and the plurality of vias of each second circuit unit includes at least a thirty-second via V32.

In an exemplary implementation, the thirty-first via V31 may be provided in each first circuit unit of the first pixel drive area 110, the orthographic projection of the thirty-first via V31 on the base substrate may be within a range of the orthographic projection of the first anode electrode 51 on the base substrate, the second planarization layer in the thirty-first via V31 is removed to expose a surface of the first anode electrode 51. The thirty-first via V31 is configured such that the first anode of the first light emitting device formed subsequently is connected with the first anode electrode 51 through the via.

In an exemplary implementation, the thirty-second via V32 may be provided in each second circuit unit of the second pixel drive area 120, the orthographic projection of the thirty-second via V32 on the base substrate may be within a range of the orthographic projection of the second anode electrode 52 on the base substrate, the second planarization layer in the thirty-second via V32 is removed to expose a surface of the second anode electrode 52. The thirty-second via V32 is configured such that the anode connection line formed subsequently is connected with the second anode electrode 52 through the via, such that the second anode of the second light emitting device formed subsequently is connected with the second anode electrode 52 through the anode connection line.

So far, the preparation of the first substrate structure layer of the first pixel drive area 110 and the second substrate structure layer of the second pixel drive area 120 on the base substrate is completed. In a plane parallel to the display substrate, the first substrate structure layer may include a plurality of first circuit units and a plurality of second circuit units. The first circuit unit may include a first pixel drive circuit, and the second circuit unit may include a second pixel drive circuit.

In an exemplary implementation, in a plane perpendicular to the display substrate, the first substrate structure layer may include a first insulation layer, a semiconductor layer, a second insulation layer, a first conductive layer, a third insulation layer, a second conductive layer, a fourth insulation layer, a third conductive layer, a first planarization layer, a fourth conductive layer and a second planarization layer stacked sequentially on the base substrate, the semiconductor layer may include at least active layers of a plurality of transistors in the first pixel drive circuit and the second pixel drive circuit, the first conductive layer may include at least gate electrodes of a plurality of transistors, a first plate of a storage capacitor, a first scan signal line, a second scan signal line and a light emitting control line, the second conductive layer may include at least a second plate of the storage capacitor, a plate connection line, a shield electrode 34, a first initial signal line and a second initial signal line, the third conductive layer may include at least first electrodes and second electrodes of the plurality of transistors, and the fourth conductive layer may include at least a first anode electrode, a second anode electrode, a compensation capacitor plate, a data signal line, and a first power supply line.

In an exemplary implementation, in a plane perpendicular to the display substrate, the second substrate structure layer may include a first insulation layer, a second insulation layer, a third insulation layer, a fourth insulation layer, a first planarization layer, and a second planarization layer that are sequentially stacked on the base substrate, that is, the second substrate structure layer is not provided with a pixel drive circuit.

In an exemplary implementation, after the preparation of the above structure layers is completed, a light emitting structure layer may be prepared on the above structure layers, and then an encapsulation structure layer may be prepared on the light emitting structure layer. The light emitting structure layer may include a first light emitting structure layer located in the first pixel drive area and a second light emitting structure layer located in the second pixel drive area, and the encapsulation structure layer may include a first encapsulation structure layer located in the first pixel drive area and a second encapsulation structure layer located in the second pixel drive area.

In an exemplary implementation, the first light emitting structure layer may include a plurality of first light emitting devices, the first light emitting devices may include at least a first anode, an organic light emitting layer, and a cathode which are stacked, the first anode is connected with the first anode electrode through the thirty-first via.

In an exemplary implementation, the second light emitting structure layer may include a plurality of second light emitting devices and anode connection lines, the second light emitting devices may at least include a second anode, an organic light emitting layer and a cathode which are stacked, a first end of the anode connection line is connected with the second anode electrode through the thirty-second via, and a second end of the anode connection line, after extending towards the second display area, is connected with the second anode.

In an exemplary implementation, the first anode, the second anode, and the anode connection line are arranged in the same layer and are formed simultaneously through a same patterning process.

In an exemplary implementation, the material of the anode connection line may be a transparent conductive material, such as indium tin oxide (ITO) or indium zinc oxide (IZO), etc.

In an exemplary implementation, the structures of the first encapsulation structure layer and the second encapsulation structure layer may be substantially the same, and may include a first encapsulation layer, a second encapsulation layer and a third encapsulation layer which are stacked, wherein the first encapsulation layer and the third encapsulation layer can be made of an inorganic material, the second encapsulation layer can be made of an organic material, and the second encapsulation layer is arranged between the first encapsulation layer and the third encapsulation layer, which may ensure that external water vapor cannot enter the light emitting structure layer.

In an exemplary implementation, the base substrate may be a flexible substrate, or may be a rigid substrate. The rigid substrate may include, but not limited to, one or more of glass and quartz. The flexible substrate may include, but not limited to, one or more of polyethylene terephthalate, ethylene terephthalate, polyether ether ketone, polystyrene, polycarbonate, polyarylate, polyarylester, polyimide, polyvinyl chloride, polyethylene, and textile fibers. In an exemplary implementation, the flexible substrate may include a first flexible material layer, a first inorganic material layer, a semiconductor layer, a second flexible material layer, and a second inorganic material layer which are stacked, wherein materials of the first flexible material layer and the second flexible material layer may be polyimide (PI), polyethylene terephthalate (PET), or a surface-treated polymer soft film, or the like. Materials of the first inorganic material layer and the second inorganic material layer may be silicon nitride (SiNx) or silicon oxide (SiOx), or the like, for improving water and oxygen resistance of the base substrate. The material of the semiconductor layer may be amorphous silicon (a-si).

In an exemplary implementation, the first conductive layer, the second conductive layer, the third conductive layer, and the fourth conductive layer may be made of metal materials, such as any one or more of silver (Ag), copper (Cu), aluminum (Al), and molybdenum (Mo), or an alloy material of the above metals, such as an Aluminum Neodymium alloy (AlNd) or a Molybdenum Niobium alloy (MoNb), and may be of a single-layer structure or a multi-layer composite structure, such as Mo/Cu/Mo. The anode connection line may use a single-layer structure, such as Indium Tin Oxide (ITO) or Indium Zinc Oxide (IZO) or may use a multi-layer composite structure, such as ITO/Ag/ITO. The first insulation layer, the second insulation layer, the third insulation layer, and the fourth insulation layer may be made of any one or more of silicon oxide (SiOx), silicon nitride (SiNx), and silicon oxynitride (SiON), and may be single-layer, multilayers, or composite layer. The first insulation layer is referred to as a buffer layer, which is used to improve water oxygen resistance of the base. The second insulation layer and the third insulation layer are referred to as gate insulation (GI) layers. The fourth insulation layer is referred to as an interlayer insulation (ILD) layer. The first planarization layer and the second planarization layer can be made of an organic material, such as resin or the like. The active layer may be made of materials such as amorphous indium gallium zinc oxide (a-IGZO), zinc oxynitride (ZnON), indium zinc tin oxide (IZTO), amorphous silicon (a-Si), polysilicon (p-Si), hexathiophene, or polythiophene, etc. That is, the present disclosure is applicable to transistors that are manufactured based on oxide technology, silicon technology or organic matter technology.

As can be seen from the structure and preparation process of the display substrate described above, exemplary embodiments of the present disclosure provide a compensation capacitor plate in the first circuit unit, the compensation capacitor plate is connected with the first anode electrode, because the first anode electrode in the first circuit unit is connected with a first anode of the first light emitting device, the compensation capacitor plate and the first anode have the same potential, and the compensation capacitor plate will form a compensation capacitor with other conductive layers. Because the second anode electrode in the second circuit unit is connected with the second anode through the anode connection line, the anode connection line and the second anode have the same potential, and the anode connection line will form a connection capacitor with other conductive layers. Thus, the structure of the first light emitting device which the first pixel drive circuit is connected to is substantially the same as the structure of the second light emitting device which the second pixel drive circuit is connected to, therefore, when the data signal line outputs a same data voltage, the brightness of the first light emitting device in the first display area and the second light emitting device in the second display area are substantially the same, thereby effectively avoiding the brightness difference between the first display area and the second display area, and improving the display attribute and the display quality.

In an exemplary implementation, a partial compensation capacitor is formed between the compensation capacitor plate and the second plate of the second conductive layer because the orthographic projection of the compensation capacitor plate on the base substrate at least partially overlaps the orthographic projection of the second plate on the base substrate.

In an exemplary implementation, a partial compensation capacitance is formed between the compensation capacitor plate and the shield electrode of the second conductive layer because the orthographic projection of the compensation capacitor plate on the base substrate at least partially overlaps the orthographic projection of the shield electrode on the base substrate.

In an exemplary implementation, a partial compensation capacitance is formed between the compensation capacitor plate and the first connection electrode of the third conductive layer because the orthographic projection of the compensation capacitor plate on the base substrate at least partially overlaps the orthographic projection of the first connection electrode on the base substrate.

In an exemplary implementation, a partial compensation capacitance is formed between the compensation capacitor plate and the second connection electrode of the third conductive layer because the orthographic projection of the compensation capacitor plate on the base substrate at least partially overlaps the orthographic projection of the second connection electrode on the base substrate.

In an exemplary implementation, a partial compensation capacitance is formed between the compensation capacitor plate and the fifth connection electrode of the third conductive layer because the orthographic projection of the compensation capacitor plate on the base substrate at least partially overlaps the orthographic projection of the fifth connection electrode on the base substrate.

In an exemplary implementation, the connection capacitance formed by the anode connection line may include any one or more of the following: the anode connection line forms a partial connection capacitance with the second plate, the anode connection line forms a partial connection capacitance with the shield electrode, the anode connection line forms a partial connection capacitance with the first connection electrode, the anode connection line forms a partial connection capacitance with the second connection electrode, the anode connection line forms a partial connection capacitance with the third connection electrode, and the anode connection line forms a partial connection capacitance with the fifth connection electrode.

FIG. 19 is a schematic diagram of an equivalent circuit of a first pixel drive circuit according to an embodiment of the present disclosure. As shown in FIG. 19, as a compensation capacitor plate is provided in the first pixel drive circuit of the exemplary embodiment of the present disclosure, the compensation capacitor plate is connected with a first electrode (first anode) of the first light emitting device LD1, it is equivalent to providing a compensation resistor RB and a compensation capacitor CB of a parallel structure between the second electrode of the sixth transistor T6 (also the second electrode of the seventh transistor T7) in the first pixel drive circuit and the first electrode of the first light emitting device LD1.

As can be seen by comparing the second pixel drive circuit shown in FIG. 9b with the first pixel drive circuit shown in FIG. 19, the second electrode of the sixth transistor T6 of the second pixel drive circuit is connected with the first electrode (second anode) of the second light emitting device LD2 through the anode connection line, it is equivalent to providing a connection resistor RL and a connection capacitor CL of a parallel structure between the second electrode of the sixth transistor T6 and the first electrode of the second light emitting device LD2 in the second pixel drive circuit. An exemplary embodiment of the present disclosure provides a compensation capacitor plate in the first pixel drive circuit, the second electrode of the sixth transistor T6 in the first pixel drive circuit is connected with the first electrode of the first light emitting device LD1 through a compensation resistor RB and a compensation capacitor CB of a parallel structure, so that the structure of the first light emitting device which the first pixel drive circuit is connected to is substantially the same as the structure of the second light emitting device which the second pixel drive circuit is connected to, therefore, when the data signal line outputs a same data voltage, the brightness of the first light emitting device in the first display area and the second light emitting device in the second display area are substantially the same, thereby effectively avoiding the brightness difference between the first display area and the second display area, and improving the display attribute and the display quality. The preparation process in the present disclosure may be compatible well with an existing preparation process, which is simple in process implementation, easy to implement, high in production efficiency and yield, and low in production cost.

In an exemplary implementation, the display substrate of an exemplary embodiment of the present disclosure may be applied to a display apparatus with a pixel drive circuit, such as an OLED, a quantum dot display (QLED), a light emitting diode display (Micro LED or Mini LED) or a quantum dot light emitting diode display (QDLED), etc., which is not limited here in the present disclosure.

The structure and preparation process thereof shown in the foregoing of the present disclosure is only an exemplary description. In an exemplary implementation, corresponding structures may be changed and patterning processes may be added or reduced according to actual needs, which is not limited here in the present disclosure.

The present disclosure further provides a manufacturing method for a display substrate, for preparing the display substrate according to the foregoing exemplary embodiments. In an exemplary implementation, the display substrate includes a first display area and a second display area, the first display area at least partially surrounds the second display area, the first display area is configured to perform image display and includes a plurality of first light emitting devices, a plurality of first circuit units and at least one second circuit unit, the second display area is configured to perform image display and transmit light, and includes a plurality of second light emitting devices; the manufacturing method may include following operations.

Forming a first circuit unit and a second circuit unit; the first circuit unit includes a first pixel drive circuit including at least a first anode electrode and a compensation capacitor plate connected with the first anode electrode, the compensation capacitor plate is configured to form a compensation capacitance; the second circuit unit includes a second pixel drive circuit which includes at least a second anode electrode.

Forming a first light emitting device and a second light emitting device; the first light emitting device is connected with the first anode electrode, and the second light emitting device is connected with the second anode electrode through an anode connection line.

The present disclosure further provides a display apparatus which includes the aforementioned display substrate. The display apparatus may be any product or component with a display function, such as a mobile phone, a tablet computer, a television, a display, a laptop computer, a digital photo frame, or a navigator, and the embodiments of the present invention are not limited thereto.

Although the implementations disclosed in the present disclosure are described as above, the described contents are only implementations which are used for facilitating the understanding for the present disclosure, but are not intended to limit the present invention. Any skilled person in the art to which the present disclosure pertains may make any modifications and variations in forms and details of implementation without departing from the spirit and scope of the present disclosure. However, the patent protection scope of the present invention should be subject to the scope defined by the appended claims.

1. A display substrate, comprising a first display area and a second display area, wherein the second display area is at least partially surrounded by the first display area, the first display area is configured to perform image display and comprises a plurality of first light emitting devices, a plurality of first circuit units and at least one second circuit unit, the second display area is configured to perform image display and transmitting light and comprises a plurality of second light emitting devices; at least one first circuit unit of the plurality of first circuit units comprises a first pixel drive circuit, the first pixel drive circuit comprises at least a first anode electrode connected with a first light emitting device of the plurality of first light emitting devices and a compensation capacitor plate connected with the first anode electrode, the compensation capacitor plate is configured to form a compensation capacitance; the second circuit unit comprises a second pixel drive circuit, the second pixel drive circuit at least comprises a second anode electrode, and the second anode electrode is connected with a second light emitting device of the plurality of second light emitting devices through an anode connection line.

2. The display substrate according to claim 1, wherein the first anode electrode, the second anode electrode and the compensation capacitor plate are disposed in a same layer and are synchronously formed through a same patterning process.

3. The display substrate according to claim 2, wherein the first anode electrode and the compensation capacitor plate are interconnected to be of an integral structure.

4. The display substrate according to claim 1, wherein the at least one second circuit unit comprises a power connection line extending along a first direction and a first power supply line extending along a second direction, the first power supply line is connected with the power connection line through a via, the first direction and the second direction are intersected.

5. The display substrate according to claim 4, wherein the first circuit unit comprises a power connection line extending along the first direction, and at least one first circuit unit is not provided with the first power supply line.

6. The display substrate according to claim 4, wherein the compensation capacitor plate and the first power supply line are disposed in a same layer and are synchronously formed through the same patterning process.

7. The display substrate according to claim 4, wherein the first circuit unit and the second circuit unit each comprises a storage capacitor, the storage capacitor comprises a first plate and a second plate, an orthographic projection of the second plate on a base substrate is at least partially overlapped with an orthographic projection of the first plate on the base substrate; the second plate of the first circuit unit is connected with the second plate of the first circuit unit adjacent in the first direction through a plate connection line to form the power connection line; or, the second plate of the first circuit unit is connected with the second plate of the second circuit unit adjacent in the first direction through a plate connection line to form the power connection line; or, the second plate of the second circuit unit is connected with the second plate of the second circuit unit adjacent in the first direction through a plate connection line to form the power connection line.

8. The display substrate according to claim 7, wherein an orthographic projection of the compensation capacitor plate on the base substrate is at least partially overlapped with an orthographic projection of the second plate of the first circuit unit on the base substrate.

9. The display substrate according to claim 1, wherein the first pixel drive circuit and the second pixel drive circuit each further comprises a first transistor as a reset transistor, a second transistor as a compensation transistor, and a third transistor as a drive transistor, a gate electrode of the first transistor is connected with a second scan signal line, a first electrode of the first transistor is connected with a first initial signal line, a second electrode of the first transistor is connected with a first electrode of the second transistor and a gate electrode of the third transistor, respectively, a gate electrode of the second transistor is connected with a first scan signal line, and a second electrode of the second transistor is connected with a second electrode of the third transistor; an orthographic projection of the compensation capacitor plate on the base substrate is at least partially overlapped with an orthographic projection of the second electrode of the first transistor of the first pixel drive circuit on the base substrate.

10. The display substrate according to claim 9, wherein the orthographic projection of the compensation capacitor plate on the base substrate is at least partially overlapped with an orthographic projection of the first electrode of the first transistor of the first pixel drive circuit on the base substrate.

11. The display substrate according to claim 9, wherein the first pixel drive circuit and the second pixel drive circuit each further comprises a fourth transistor as a data writing transistor and a fifth transistor as a light emitting control transistor, a gate electrode of the fourth transistor is connected with the first scan signal line, a first electrode of the fourth transistor is connected with a data signal line, a second electrode of the fourth transistor is connected with a first electrode of the third transistor, a gate electrode of the fifth transistor is connected with a light emitting control line, a first electrode of the fifth transistor is connected with a second plate of a storage capacitor, and a second electrode of the fifth transistor is connected with a first electrode of the third transistor; the orthographic projection of the compensation capacitor plate on the base substrate is at least partially overlapped with an orthographic projection of the first electrode of the fifth transistor of the first pixel drive circuit on the base substrate.

12. The display substrate according to claim 9, wherein the first pixel drive circuit and the second pixel drive circuit each further comprises a sixth transistor as a light emitting control transistor, a gate electrode of the sixth transistor is connected with a light emitting control line, a first electrode of the sixth transistor is connected with the second electrode of the third transistor, the first anode electrode is connected with a second electrode of the sixth transistor of the first circuit unit through a via hole, and the second anode electrode is connected with a second electrode of the sixth transistor of the second circuit unit through a via hole.

13. The display substrate according to claim 12, wherein the first pixel drive circuit and the second pixel drive circuit each further comprises a seventh transistor as a reset transistor, a gate electrode of the seventh transistor is connected with the second scan signal line, a first electrode of the seventh transistor is connected with a second initial signal line, and a second electrode of the seventh transistor is connected with the second electrode of the sixth transistor.

14. The display substrate according to claim 9, wherein the first pixel drive circuit and the second pixel drive circuit each further comprises a shield electrode connected with the first initial signal line, and the orthographic projection of the compensation capacitor plate on the base substrate is at least partially overlapped with an orthographic projection of the shield electrode of the first pixel drive circuit on the base substrate.

15. The display substrate according to claim 1, wherein a first end of the anode connection line is connected with the second anode electrode through a via hole, and a second end of the anode connection line is extended to the second display area and is connected with a second anode of the second light emitting device.

16. The display substrate according to claim 1, wherein in a direction perpendicular to the display substrate, the first display area comprises a first substrate structure layer disposed on a base substrate and a first light emitting structure layer disposed on a side of the first substrate structure layer away from the base substrate, the first substrate structure layer comprises the plurality of first circuit units and the at least one second circuit unit, and the first light emitting structure layer comprises the plurality of first light emitting devices; the second display area comprises a second substrate structure layer disposed on the base substrate and a second light emitting structure layer disposed on a side of the second substrate structure layer away from the base substrate, the second substrate structure layer comprises a plurality of insulation layers, and the second light emitting structure layer comprises the plurality of second light emitting devices.

17. The display substrate according to claim 16, wherein the first substrate structure layer comprises a first conductive layer, a second conductive layer, a third conductive layer and a fourth conductive layer provided sequentially on the base substrate, the first conductive layer comprises gate electrodes of a plurality of transistors in the first pixel drive circuit and the second pixel drive circuit and a first plate of a storage capacitor, the second conductive layer comprises a second plate of the storage capacitor, the third conductive layer comprises first electrodes and second electrodes of the plurality of transistors, and the fourth conductive layer comprises the first anode electrode, the second anode electrode and the compensation capacitor plate.

18. The display substrate according to claim 17, wherein the fourth conductive layer further comprises a first power supply line disposed at the second circuit unit.

19. A display apparatus, comprising the display substrate according to claim 1.

20. A manufacturing method for a display substrate, wherein the display substrate comprises a first display area and a second display area, the second display area is at least partially surrounded by the first display area, the first display area is configured to perform image display and comprises a plurality of first light emitting devices, a plurality of first circuit units and at least one second circuit unit, the second display area is configured to perform image display and transmitting light and comprises a plurality of second light emitting devices, the manufacturing method comprising:
forming the plurality of first circuit units and the at least one second circuit unit, wherein at least one first circuit unit of the plurality of first circuit units comprises a first pixel drive circuit, the first pixel drive circuit comprises at least a first anode electrode and a compensation capacitor plate connected with the first anode electrode, the compensation capacitor plate is configured to form a compensation capacitance; the second circuit unit comprises a second pixel drive circuit which comprises at least a second anode electrode; and
forming the plurality of first light emitting devices and the plurality of second light emitting devices, wherein at least one first light emitting device of the plurality of first light emitting devices is connected with the first anode electrode, and at least one second light emitting device of the plurality of second light emitting devices is connected with the second anode electrode through an anode connection line.
